(19) United States
(12) Patent Application Publication
(10) Pub. No.: US 2004/0147121 A1
(43) Pub. Date: Jul. 29, 2004

(54) Method and system for manufacturing a semiconductor device

(75) Inventors: Ryo Nakagaki, Kawasaki (JP); Kenji Watanabe, Hitachinaka (JP); Yuya Toyoshima, Sendai (JP); Chie Shishido, Yokohama (JP); Yuji Takagi, Kamakura (JP); Maki Tanaka, Yokohama (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: Hitachi, Ltd., Tokyo (JP); Hitachi High-Technologies Corporation, Tokyo (JP)

(21) Appl. No.: 10/699,528

(22) Filed: Oct. 31, 2003

(30) Foreign Application Priority Data
Nov. 1, 2002 (JP) JP 2002-319833

(51) Int. Cl. H01L 21/302; H01L 21/461

(52) U.S. Cl. 438/689

(57) ABSTRACT

Disclosed are a method and a system for manufacturing a semiconductor device by which it is possible to manufacture a semiconductor device while enabling evaluation of a manufacturing process for a super-miniaturized actual circuit pattern at a high speed by utilizing a three-dimensional measuring technique based on the use of an optical scatterometry apparatus. The method of manufacturing a semiconductor device comprising the step of forming a test pattern and an actual circuit pattern by a predetermined semiconductor manufacturing process, to thereby manufacture a product semiconductor device, wherein features of the three-dimensional shape of the test pattern formed in the product semiconductor device are measured by use of the optical scatterometry apparatus, and the semiconductor manufacturing process for the actual circuit pattern of the product semiconductor device is thereby evaluated.

### BACKGROUND OF THE INVENTION

The present invention relates to a method and a system for manufacturing a semiconductor device through evaluation of a super-miniaturized circuit pattern formed in a semiconductor device such as a semiconductor memory and an integrated arithmetic circuit.

In recent years, manufacture of semiconductor devices has progressed to a super-miniaturization in which a circuit pattern formed in a semiconductor device is on the order of not more than 0.1 μm, specifically on the order of several tens of nanometers. On the other hand, upon manufacture of a semiconductor, it is necessary to evaluate the manufacturing process.

Meanwhile, in the case of a miniaturized circuit pattern on the order of not less than about 0.2 μm, it has been possible to sufficiently evaluate and monitor the manufacturing process by only measuring the two-dimensional shape of the miniaturized circuit pattern by use of a CD-SEM (Scanning Electron Microscope), for example. In addition, in the case of a CD-SEM, there have been the problems that the principle of irradiating a wafer with an electron beam to observe the wafer may lead to damage to patterns weak to the irradiation with the electron beam and that the necessity for placing the wafer in a vacuum atmosphere leads to a long time being required for preparation therefor.

On the other hand, in the case of a super-miniaturized circuit pattern on the order of not more than 0.1 μm as above-mentioned, it is necessary to measure the three-dimensional shape of the circuit pattern because sidewall angle, bottom corner roundness, top roundness and the like have influences. Conventionally, therefore, a method in which an object portion of the super-miniaturized circuit pattern is cleaved or is cut off by FIB or the like and the section is observed under a cross sectional SEM has been adopted, as described, for example, in Japanese Patent Laid-open No. Hei 4-273134 (patent document 1) and Japanese Patent Laid-open No. 2001-127125 (patent document 2). The cross sectional SEM is a microscope for observing the section of a cleaved wafer, and is a tool for direct observation of the sectional shape of a pattern. The cross sectional SEM has the merit of direct observation but also has the demerit that the wafer must be cleaved; therefore, the cross sectional SEM is rarely used in a mass production line and is used mostly at the stage of process development.

In addition, an AFM (Atomic Force Microscope) described, for example, in Japanese Patent Publication No. Hei 7-52102 (patent document 3) is used as another tool for measuring a three-dimensional shape. Use of an AFM makes it possible to observe the three-dimensional shape of a circuit pattern without cleaving the wafer, but there arises the problem that it takes a long time for measurement.

Furthermore, a technique of measuring a three-dimensional shape by use of an optical scatterometry apparatus is known, as described in U.S. Pat. No. 5,867,276 (patent document 4) and Published Japanese Translation of PCT Patent Application No. 2002-506217 (patent document 5).

In view of the present circumstances in which a circuit pattern formed in a semiconductor is progressively super-miniaturized on the order of not more than 0.1 μm, specifically on the order of several tens of nanometers, it has become necessary to measure a three-dimensional shape. As a result, the measurement through observation of a section by use of a cross sectional SEM as described in patent documents 1 and 2 has the problem that the throughput is low and the measuring apparatus is complicated and increased in cost.

On the other hand, use of an AFM is disadvantageous in that the measuring time is long.

Furthermore, patent documents 4 and 5 have no sufficient consideration for evaluation of a manufacturing process of a super-miniaturized circuit pattern.

### SUMMARY OF THE INVENTION

It is an object of the present invention to provide a method and a system for manufacturing a semiconductor device in which it is made possible to evaluate a manufacturing process of a super-miniaturized actual circuit pattern and to manufacture a semiconductor device by utilizing a three-dimensional measurement technique based on an optical scatterometry apparatus.

It is another object of the present invention to provide a system for manufacturing a semiconductor device in which it is made possible to control manufacturing process conditions so as to obtain an appropriate finish of a super-miniaturized actual pattern based on the results of three-dimensional measurement of a test pattern by an optical scatterometry apparatus.

In accordance with one aspect of the present invention, there is provided a method of manufacturing a semiconductor device, for manufacturing the semiconductor device through forming a test pattern and an actual pattern by a predetermined manufacturing process, wherein features of the three-dimensional shape of a test pattern formed in the semiconductor device are measured by use of an optical scatterometry apparatus, and the manufacturing process for the actual pattern in the semiconductor device is thereby evaluated.

In accordance with another aspect of the present invention, there is provided a method of manufacturing a semiconductor device comprising: a preparation step which comprises the steps of preliminarily forming a sample wafer provided with a test pattern and an actual circuit pattern through varying process parameters in a semiconductor manufacturing process, measuring features of the three-dimensional shape of the test pattern formed as the sample wafer and features of the three-dimensional shape of a predetermined portion of the actual circuit pattern formed as the sample wafer, and calculating and preparing the correspondence relationships between the features of the three-dimensional shape of the test pattern and the features of the three-dimensional shape of the predetermined portion of the actual circuit pattern thus measured when the process parameters (manufacturing process conditions) are varied; and an evaluation step which comprises, in manufacturing a product semiconductor device through forming a test pattern and an actual circuit pattern by a predetermined product semiconductor manufacturing process, the steps of measuring features of the three-dimensional shape of the test pattern formed in the product semiconductor device by use of an optical scatterometry apparatus, and evaluating the semiconductor manufacturing process for the actual circuit pattern in the product semiconductor device according to the correspondence relationships upon variation of the process parameters prepared in the preparation step, based on the features of the three-dimensional shape of the test pattern thus measured.

In accordance with a further aspect of the present invention, there is provided a method of manufacturing a semiconductor device comprising: a preparation step which comprises the steps of preliminarily forming a sample wafer provided with a test pattern and an actual circuit pattern through varying process parameters in a semiconductor manufacturing process, measuring features of the three-dimensional shape of the test pattern formed as the sample wafer and features of the three-dimensional shape of a predetermined portion of the actual circuit pattern formed as the sample wafer, and calculating and preparing the correspondence relationships between the features of the three-dimensional shape of the test pattern and the features of the three-dimensional shape of the predetermined portion of the actual circuit pattern thus measured when the process parameters (manufacturing process conditions) are varied; and an evaluation step which comprises, in manufacturing a product semiconductor device through forming a test pattern and an actual circuit pattern by a predetermined product semiconductor manufacturing process, the steps of measuring features of the three-dimensional shape of the test pattern formed in the product semiconductor device by use of an optical scatterometry apparatus, estimating features of the three-dimensional shape of a predetermined portion of the actual circuit pattern based on the correspondence relationships upon variation of the process parameters prepared in the preparation step, and evaluating the semiconductor manufacturing process for the actual circuit pattern in the product semiconductor device, based on the features of the three-dimensional shape thus estimated.

In accordance with still another aspect of the present invention, there is provided a method of manufacturing a semiconductor device comprising: a preparation step comprising the steps of preliminarily forming a sample wafer provided with a test pattern and an actual circuit pattern through varying process parameters in a semiconductor manufacturing process, measuring features of the three-dimensional shape of the test pattern formed as the sample wafer and features of the three-dimensional shape of a predetermined portion of the actual circuit pattern formed as the sample wafer, setting ranges of the process parameters (ranges of manufacturing process conditions) required for the features of the three-dimensional shape of the predetermined portion of the actual circuit pattern upon variation of the process parameters (manufacturing process conditions) thus measured to satisfy the features of the three-dimensional shape of a criterion (acceptable product), and calculating and preparing the features of the three-dimensional shape of the test pattern measured within the ranges of the process parameters thus set (in other words, the correspondence relationships between the features of the three-dimensional shape of the test pattern and the features of the three-dimensional shape of the predetermined portion of the actual circuit pattern when the process parameters (manufacturing process conditions) are varied); and an evaluation step which comprises, in manufacturing a product semiconductor device through forming a test pattern and an actual circuit pattern by a predetermined product semiconductor manufacturing process, the steps of measuring features of the three-dimensional shape of the test pattern formed in the product semiconductor device by use of an optical scatterometry apparatus, and evaluating the semiconductor manufacturing process for the actual circuit pattern in the product semiconductor device by judging whether or not the features of the three-dimensional shape of the test pattern measured are within the ranges of the process parameters, based on the features of the three-dimensional shape of the test pattern calculated within the ranges of the process parameters prepared in the preparation step.

In accordance with a still further aspect of the present invention, there is provided a system for manufacturing a semiconductor device, comprising: a preparation unit for preliminarily measuring features of the three-dimensional shape of a test pattern and features of the three-dimensional shape of a predetermined portion of an actual circuit pattern, for a plurality of sample wafers each provided with the test pattern and the actual circuit pattern through varying process parameters in a semiconductor manufacturing process, and calculating and preparing the correspondence relationships between the features of the three-dimensional shape of the test pattern and the features of the three-dimensional shape of the predetermined portion of the actual circuit pattern upon variation of the process parameters (manufacturing process conditions) thus measured; and an evaluation unit, in manufacturing a product semiconductor device formed with a test pattern and a actual circuit pattern by a predetermined product semiconductor manufacturing process, for measuring features of the three-dimensional shape of the test pattern formed in the product semiconductor device by use of an optical scatterometry apparatus, and evaluating the semiconductor manufacturing process for the actual circuit pattern in the product semiconductor device according to the correspondence relationships upon variation of the process parameters prepared by the preparation unit, based on the features of the three-dimensional shape of the test pattern thus measured.

These and other objects, features and advantages of the invention will be apparent from the following more particular description of preferred embodiments of the invention, as illustrated in the accompanying drawings.

### BRIEF DESCRIPTION OF THE DRAWINGS

FIG. 1 illustrates a photo step and an etching step in a process of manufacturing a semiconductor device according to the present invention;

FIGS. 2A and 2B illustrate the sectional shape of a super-fine line pattern according to the present invention;

FIG. 3 illustrates the sectional shape of a super-fine hole pattern according to the present invention;

FIGS. 4A to 4D illustrate super-fine actual circuit patterns according to the present invention as two-dimensionally observed from above;

FIGS. 5A and 5B illustrate a semiconductor wafer and a chip, respectively, according to the present invention;

FIG. 6 is a perspective view of one embodiment of a test pattern consisting of a line-and-space pattern according to the present invention;

FIG. 7 is a schematic diagram showing one embodiment of an optical scatterometry apparatus according to the present invention;

FIG. 8 is a diagram showing one embodiment of scattered light intensity distribution obtained from a spectral unit shown in FIG. 7, where a test pattern is the object of measurement;

FIG. 9 schematically illustrates a shape variation of a sectional pattern of a super-fine wire generated due to variations in amounts of exposure and focus values;

FIGS. 10A and 10B illustrate an embodiment of the sectional shaped model of a line pattern pre-defined for measurement of the three-dimensional shape of a test pattern by the optical scatterometry apparatus according to the present invention;

FIG. 11 illustrates the configuration of one embodiment of a measuring system, which is a system for manufacturing a semiconductor device according to the present invention;

FIGS. 12A and 12B are process flow charts showing first and second embodiments of a pre-processing for preparation according to the present invention, and first and second embodiments of measurement processing for evaluating manufacturing process conditions at the time of manufacturing a product according to the present invention;

FIGS. 13A and 13B illustrate the correspondence relationship between a test pattern and an actual circuit pattern as to a wire width (line width) at each amount of exposure and each focus value which are process conditions according to the present invention;

FIGS. 14A and 14B illustrate the correspondence relationship between a test pattern and an actual circuit pattern as to a sidewall angle at each amount of exposure and each focus value which are process conditions according to the present invention;

FIGS. 15A and 15B are process flow charts showing a third embodiment of pre-processing for preparation according to the present invention, and a third embodiment of a measurement processing for evaluating manufacturing process conditions at the time of manufacturing a product according to the present invention;

FIG. 16 is a diagram showing the relationship between an amount of exposure, which is a process condition, and a wire width (line width), which is a feature of the three-dimensional shape of a test pattern;

FIG. 17 is a diagram showing, by use of a fitting function, the relationship between an amount of exposure, which is a process condition, and a wire width (line width), which is a feature of the three-dimensional shape of a test pattern;

FIG. 18 is a diagram showing the correspondence relationship between a test pattern and a critical actual circuit pattern, in the case where an amount of exposure constitutes a process condition and a wire width (line width) is a feature of a three-dimensional shape;

FIG. 19 is a diagram showing stored data of features of three-dimensional shape and process parameters in a correlated table form, for test patterns at a plurality of locations and critical actual circuit patterns at a plurality of locations;

FIG. 20 illustrates a test pattern and a critical actual circuit pattern in a chip;

FIG. 21 illustrates an embodiment of displaying the measurements in the first embodiment of the measuring system shown in FIG. 11;

FIG. 22 illustrates the configuration of a second embodiment (process monitoring system) of the measuring system, which is a system for manufacturing a semiconductor device according to the present invention;

FIGS. 23A and 23B are process flow charts showing a fourth embodiment of a pre-processing for preparation according to the present invention, and a fourth embodiment of a measurement processing for evaluating manufacturing process conditions at the time of manufacturing a product according to the present invention;

FIG. 24 illustrates the setting of a process window for the relationship between process variations and three-dimensional shape variations;

FIG. 25 exemplifies process windows set for an actual circuit pattern and a test pattern; and

FIG. 26 illustrates an embodiment of displaying the measurements in the second embodiment of the measuring system shown in FIG. 22.

### DESCRIPTION OF THE PREFERRED EMBODIMENTS

Preferred embodiments of a method of manufacturing a semiconductor device comprising a super-fine circuit pattern of not more than 0.1 μm in size according to the present invention will be described referring to the drawings.

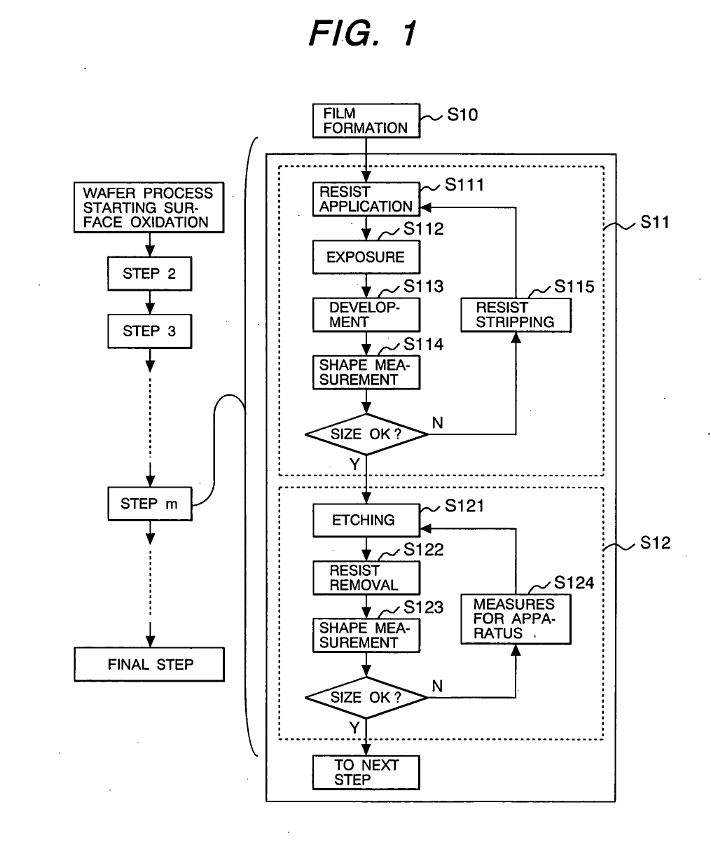

FIG. 1 shows the flow of a lithography process at the time of manufacturing a semiconductor device according to the present invention. The lithography process is comprised of a photo step S11 for forming a resist pattern by exposure and development, and an etching step S12 for transferring the resist pattern to a film to be processed. A best thin film to be processed is preliminarily formed on a semiconductor wafer (S10). A resist which is a photosensitive material is applied (coated) to the thin film in a predetermined thickness (S111), a mask pattern is exposed by use of an exposure apparatus (S112), and then development is performed to form a resist pattern (S113). The shape of the resist pattern thus formed is measured by various measuring instruments (S114), and, when the measured shape does not satisfy the specifications thereof, the resist pattern is stripped (S115), and the resist application step S111 is re-entered, in which the exposure condition is modified and then the pattern is re-formed.

Next, using the thus formed resist pattern as a mask, the thin film preliminarily formed beneath the resist is etched to thereby transform the resist pattern and form a circuit pattern (S121). At present, most of super-fine circuit patterns of semiconductors are processed by dry etching using plasma. After the resist is removed in S122, the shape of the circuit pattern is measured by various measuring instruments (S123), in the same manner as in the case of the resist pattern. In the case of the etching processing, the wafer cannot be re-processed. Therefore, when abnormality is confirmed, the starting of the wafer processing is stopped, and investigation of the cause of the abnormality and a measure against the cause are made (S124). When the pattern is formed normally, the film formation, photo, and etching steps are repeated in the same manner as above, to form a multi-layer circuit.

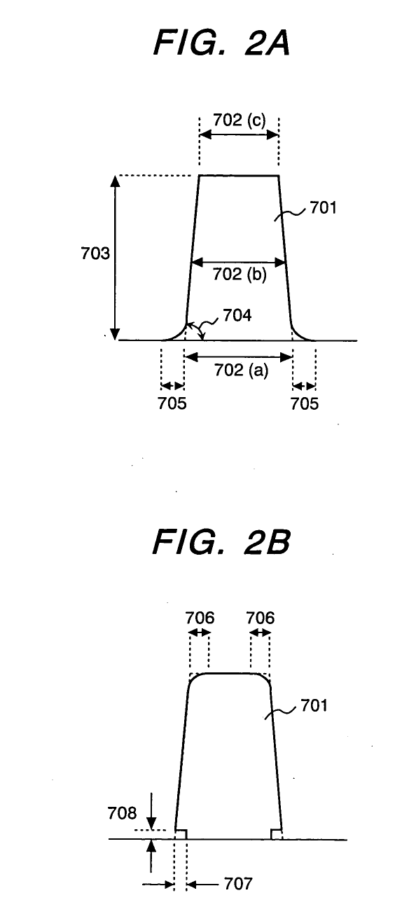

As embodiments of the shape of the super-fine circuit pattern constituting the object of three-dimensional shape measurement, sectional views of line patterns formed on a wafer are shown in FIGS. 2A and 2B. In FIGS. 2A and 2B, the material of the super-fine circuit pattern portion 701 is the resist in the case of the pattern after the photo step, and is the thin film which is a target of pattern formation in the case of the pattern after the etching. In FIGS. 2A and 2B, as embodiments of the shape features characterizing the three-dimensional shape of the super-fine circuit pattern, there are shown a wire width (line width) 702, a film thickness 703, a sidewall angle 704, a bottom corner roundness 705, a top corner roundness 706, a notch depth 707, and a notch height 708. As for the wire width (line width), there are shown a top wire width 702(a), a middle wire width 702(b), and a bottom wire width 702(c), according to the difference in the position of measurement in the height direction.

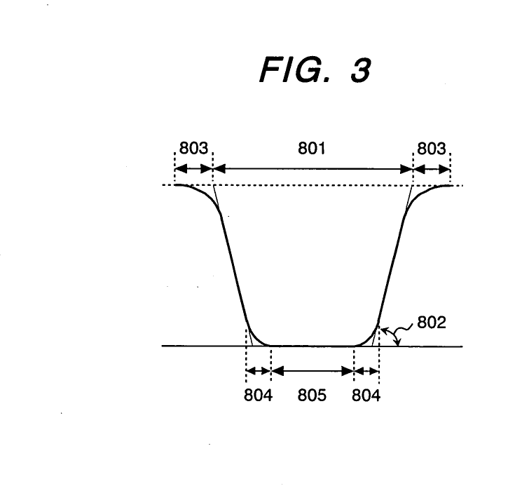

FIG. 3 shows a sectional view of a hole pattern, as another embodiment of the shape of the super-fine circuit pattern, which is the object of three-dimensional shape measurement. In the case of the hole pattern, a top diameter 801, a sidewall angle 802, a top corner roundness 803, a bottom corner roundness 804, a bottom diameter 805 and the like are the shape features characterizing the three-dimensional shape thereof.

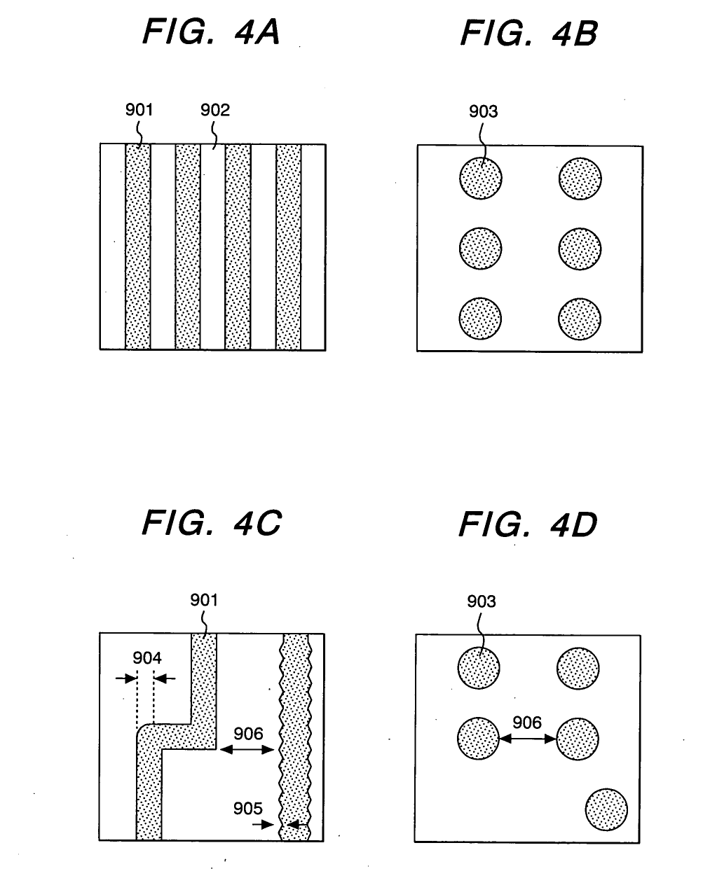

FIGS. 4A to 4D illustrate embodiments of super-fine actual circuit patterns formed on a semiconductor wafer for manufacturing a semiconductor device, as observed from the upper side. FIG. 4A shows a line-and-space pattern in which line patterns 901 and space patterns 902 are arranged alternately, and FIG. 4B shows an actual pattern in which hole patterns 903 are arranged. In a semiconductor wafer, not only these actual patterns comprising patterns arranged regularly but also actual patterns comprising various patterns arranged at random, as shown in FIGS. 4C and 4D, may be present. In the case of observing the actual pattern from the upper side, a corner roundness 904, a pattern edge fluctuation (a pattern edge roughness) 905, a pattern-to-pattern interval 906 and the like of the patterns 901 may also be shape features.

Meanwhile, the sectional shape of the super-fine actual circuit pattern (hereinafter referred to simply as the actual circuit pattern) shown in FIGS. 2A, 2B and 3 are varied variously according to variations of the process conditions in the photo and etching steps. For example, in the photo step, the amount of exposure and the focus value at the time of exposure of a pattern are principal process conditions, and the shape of the actual circuit pattern formed is varied according to variations in the values of these principal process conditions. In addition, in the etching step, the process conditions causing variations in the shape of the actual circuit pattern include the kind of the etching gas, the flow rate of the gas, the pressure of the gas, etching time, plasma discharge power, bias power impressed on the specimen, wafer temperature, etc.

In the site of manufacturing a semiconductor, various process conditions are so regulated that the shape of the actual circuit pattern after either of photo and etching steps satisfies certain criteria (the regulation is generally called condition determination (recipe set-up)), and a wafer is manufactured according to the regulated process conditions. In this case, the process conditions may vary (drift) with time. Therefore, it is necessary to constantly measure the shape of the actual circuit pattern being formed and to monitor whether or not the shape of the actual circuit pattern satisfies the criteria.

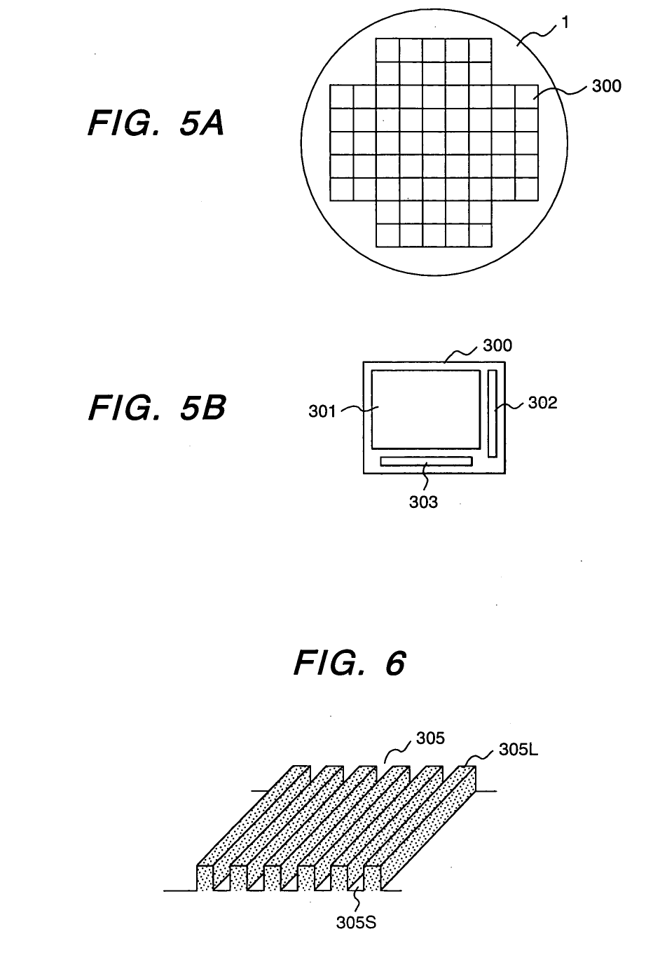

In view of the above, according to the present invention, use is made of an optical scatterometry apparatus capable of measuring (observing) the three-dimensional shape of a circuit pattern at high speed. In the case of using the optical scatterometry apparatus, however, the principle of measurement makes it difficult to measure various actual circuit patterns as shown in FIGS. 4A to 4D. Taking this into account, according to the present invention, chips 300 are arranged on a semiconductor wafer 1 as shown in FIG. 5A, the three-dimensional shape of a super-fine test pattern (hereinafter referred to simply as test pattern) produced in scribe regions 302 and 303 of the chip 300 by the same process as that for producing the actual circuit pattern in a chip main body 301 is measured by use of the optical scatterometry apparatus. For example, the super-fine test pattern is a line-and-space pattern in which a multiplicity of the same line patterns constituted of pattern lines 304L and space portions 305S are arranged as shown in FIG. 6. Thus, the three-dimensional shape of a critical circuit pattern in the actual circuit pattern is estimated.

Therefore, in order to enhance the accuracy of estimate as much as possible, it is necessary to allow the wire width (line width), space width, and space depth of the test pattern to approximate the three-dimensional shape of the critical circuit pattern. In addition, since the same pattern is repeated in a certain direction in the test pattern 305, the influences of directionality can be eliminated by providing the test pattern having the same pattern repeated in X direction and the test pattern having the same pattern repeated in Y direction in the scribe regions 302 and 303. Furthermore, the test pattern 305 can also be provided in the chip main body 301 other than the scribe regions.

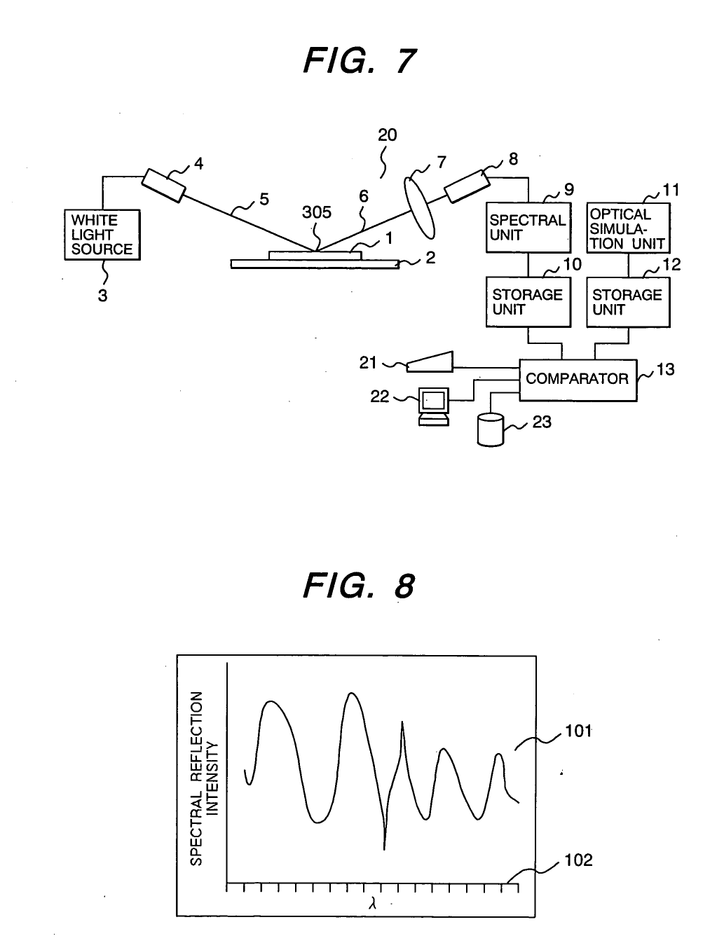

FIG. 7 is a schematic diagram showing one embodiment of the optical scatterometry apparatus according to the present invention. White light from a white light source 3 is made to be incident on an objective lens 4, and then impinges on a test pattern 305 as a measurement point on a semiconductor wafer 1. The incident light 5 has a specified angle, and reflected light 6 having an angle optically symmetrical with respect to the specified angle is condensed by a condenser lens 7, and then received by a light receiving unit 8. The light from the light receiving unit 8 is spectrally split, then reflection intensity of the test pattern 305 at each wavelength is measured, and the measurement results are stored in a storage unit 10.

The semiconductor wafer 1 as the object of measurement is mounted on a stage 2, and the stage 2 is moved in a scanning manner, whereby the test pattern 305 at an arbitrary location on the semiconductor wafer 1 can be irradiated with light. In addition, the stage 2 can be moved in XYZ directions and a rotating direction (θ), so that a spectral waveform can be detected at different angles θ for the same measurement point.

FIG. 8 illustrates an embodiment of the spectral reflection intensity distribution 101, with the axis of abscissas 102 indicating measurement wavelength A, and the axis of ordinates indicating spectral reflection intensity.

In the optical scatterometry apparatus 20 according to the present invention, the super-fine test pattern 305 shown in FIG. 6 is made to be the object of measurement. The scattered light intensity distribution which is detected from the spectral unit (the spectrometer) 9 by use of an optical system shown in FIG. 7 and stored in the storage unit 10 and the intensity distribution of scattered light generated from a modeled repeated pattern shape (three-dimensional shape) which is obtained by optical simulation in an optical simulation unit 11 and stored in a storage unit 12 are compared with each other in a comparator 13. In addition, such a model that both the scattered light intensity distributions coincide with each other is outputted as a three-dimensional shape of the test pattern which is the object of measurement.

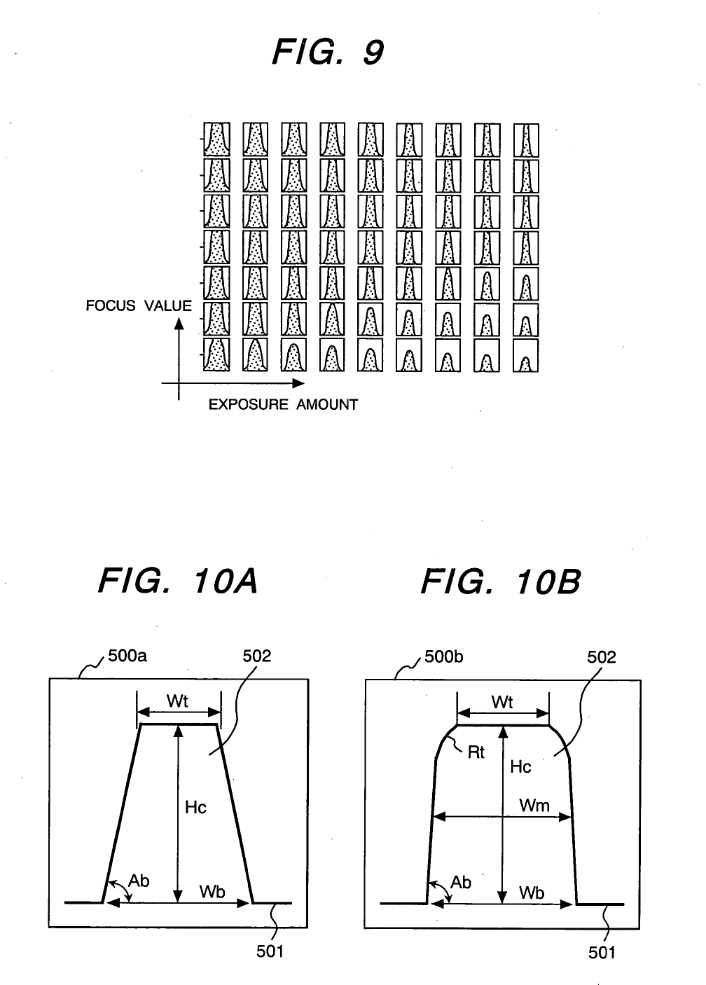

Here, as a specific embodiment, the case of using the optical scatterometry apparatus for judging the process conditions of a wafer exposure step will be described. The principal process conditions in the wafer exposure step are an amount of exposure and focus. FIG. 9 schematically expresses variations in the sectional pattern of super-fine wiring generated due to variations in the exposure amount and the focus value. FIG. 9 shows the manner of variation in the wire width (line width) due to variation of the amount of exposure and the manner of variation in the sidewall angle of the wire due to variation of the focus value.

Thus, when the variation of the three-dimensional shape of a super-fine pattern due to the variations in amount of exposure and focus value is utilized, it is possible to obtain the amount of exposure and the focus value in the process in question by measuring (examining) the wire width and sidewall angle in the sectional shape of the test pattern 305 in an actual wafer.

In the optical scatterometry apparatus 20, models 500a and 500b of the sectional shape defined preliminarily for measuring the three-dimensional shape of the test pattern 305 exposed and developed as shown in FIG. 9 are shown in FIGS. 10A and 10B, respectively. Specifically, where the test pattern 305 is, for example, the line-and-space pattern shown in FIG. 6, the models 500a and 500b having sectional shapes as shown in FIGS. 10A and 10B, respectively, are constructed. The models 500a and 500b are each constituted of a line portion 502 and a space portion 501. As shown in FIG. 10A, for example, a top width Wt, a bottom width Wb, a sidewall angle Ab, a film thickness Hc, and the like are set as parameters of sectional shape. In addition, various values are assigned to the corresponding parameters, whereby various sectional shapes as shown in FIG. 9 can be expressed. Where a middle width, a top corner roundness, a bottom corner roundness, a notch depth, a notch height, and the like are taken into consideration, it is naturally necessary to prepare them as sectionally shaped models. FIG. 10B shows the case where a middle width Wm and a top corner roundness Rt are set as parameters of sectional shape, in addition to a top width Wt, a bottom width Wb, a sidewall angle Ab, and a film thickness Hc.

As has been described above, an upper limit, a lower limit, and a variation step are determined for each of the parameters of sectional shape, the scattered light intensity distribution is calculated by the optical simulation unit 11 for each of shape models corresponding to all combinations of the parameters, and the results of calculation are stored as a library in the storage unit 12. That is, in forming the library, the upper and lower limits and the variation step of each sectional shape parameter are obtained from the ranges of shape variation shown in FIG. 9.

For example, where the designed wire width is 80 nm, the film thickness is 100 nm and the sidewall angle is 90 degrees, Wt and Wb are varied from 70 nm to 90 nm by steps of 1 nm, Hc is varied from 90 nm to 110 nm by steps of 1 nm, and Ab is varied from 88 degrees to 92 degrees by steps of 1 degree. The upper limits, the lower limits and the steps are determined according to the degree of fineness to which the exposure process conditions such as an amount of exposure and a focus value are to be controlled. Then, for each of the shape models corresponding to all combinations of the parameters of sectional shape, the scattered light intensity distribution is calculated in the optical simulation unit 11. All the scattered light intensity distributions thus calculated are stored as a library in the storage unit 12.

Incidentally, at the time of calculating the scattered light intensity distribution for each of various shape models, correction is performed by obtaining correction factors according to the material of the test pattern 305 (resist pattern, metallic thin film pattern, etc.) and the illumination conditions (illumination intensity, illumination angle, and illumination flux diameter (beam west diameter)) of white light in the optical scatterometry apparatus. This makes it possible to adjust the scattered light intensity distribution calculated to the scattered light intensity distribution detected from the optical scatterometry apparatus.

At the time of measuring the sectional shape (three-dimensional shape) of the test pattern 305 formed together with the super-fine actual circuit pattern on the semiconductor wafer 1 for manufacturing a semiconductor device, the scattered light intensity distribution of the test pattern 305 is measured from the spectral unit 9 by use of the optical system shown in FIG. 7, and is stored in the storage unit 10. A comparison unit (retrieval unit) 13 constituted of a control CPU searches the library 1 for a scattered light intensity distribution closest to the measured scattered light intensity distribution stored in the storage unit 10. A sectional shape corresponding to the scattered light intensity distribution in the library thus searched is deemed as the sectional shape of the test pattern 305, and the sectional shape (three-dimensional shape) parameters such as the wire width (line width) and the sidewall angle are obtained and outputted.

Input means such as a keyboard, a mouse and a network, output means such as a display unit, a storage unit 23 and the like are connected to the control CPU 13. The optical simulation unit 11 may be composed of the control CPU.

In this manner, the sectional shapes (three-dimensional shapes) of most of the test patterns 305 formed in correspondence with the chips under the same process conditions as the actual circuit patterns on the semiconductor wafer 1 can be measured, and whether or not an acceptable semiconductor device can be manufactured in high yield can be evaluated by estimating the sectional shape of the critical actual circuit pattern in the actual circuit pattern.

In the optical scatterometry apparatus 20, however, the measurement of a sectional shape is possible only for a repeated pattern. Therefore, for example where a defect is present in the line portion or the space portion of the test pattern 305, the sectional shape can be misrecognized (mismeasured). Accordingly, a two-dimensional image (plan image) of the super-fine test pattern 305 is obtained by a CD-SEM (not shown) arranged side by side with the optical scatterometry apparatus 20, so as to check the presence or absence of a defect in the test pattern 305, whereby it is possible, when a defect is present, to judge that the sectional shape measured by the optical scatterometry apparatus is not correct.

In addition, by comparing the two-dimensional shape of an upper portion of the sectional shape (three-dimensional shape) of the test pattern measured by the optical scatterometry apparatus 20 with the two-dimensional shape of an upper portion of the test pattern measured by the CD-SEM to check the degree of discrepancy, and feeding back the thus checked degree of discrepancy to the optical simulation unit 11 of the optical scatterometry apparatus 20, it is possible to compensate the shape model for the discrepancy.

Next, the estimate of the three-dimensional shape of the actual circuit pattern at a critical portion of the actual circuit pattern formed on the semiconductor wafer 1 under the same process conditions, based on the three-dimensional shape of the test pattern 305 measured by the optical scatterometry apparatus 20, will be described specifically. That is, design data constituted of the three-dimensional shape of the actual circuit pattern (comprising random circuit patterns) formed in a chip can be obtained from a design CAD system (not shown).

Meanwhile, the test pattern 305 and the actual circuit pattern formed on the semiconductor wafer 1 are basically formed under the same process conditions, so that they have a certain correlation with each other in many cases. Since an actual circuit pattern comprises circuit patterns in various shapes, a portion which is most severely susceptible to influences of the surrounding circuit patterns (a critical portion) is present in manufacturing an acceptable semiconductor device. In view of this, it is necessary to estimate the three-dimensional shape of the actual circuit pattern at the critical portion, based on the three-dimensional shape of the test pattern 305 measured by the optical scatterometry apparatus, and to thereby evaluate the manufacturing process conditions. Therefore, it is necessary to preliminarily associate the three-dimensional shape of the test pattern 305 with the three-dimensional shape of the actual circuit pattern at the critical portion. Incidentally, the critical portion can be empirically designated among the design data outputted to a display unit, and can be inputted to the control CPU 13.

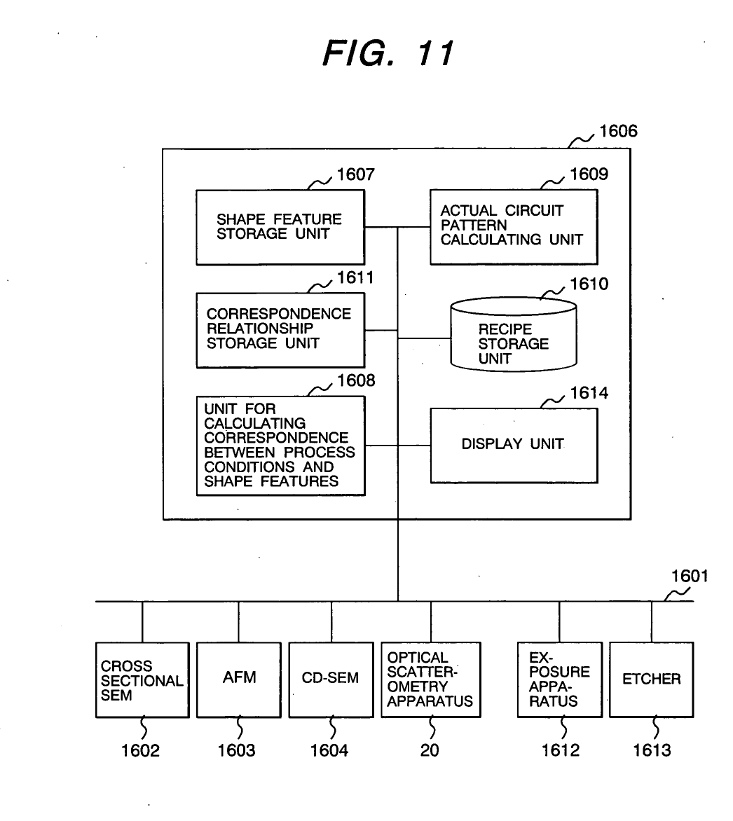

Next, a first embodiment of the measuring system which is a system for manufacturing a semiconductor device according to the present invention will be described referring to FIG. 11. The first embodiment of the measuring system has a configuration in which measuring instruments such as an optical scatterometry apparatus 20, a CD-SEM 1604, an AFM 1603 and a cross sectional SEM 1602 and manufacturing apparatuses such as an exposure apparatus 1612 and an etcher 1613 are connected onto a network 1601. These are capable of data communication with a server 1606. Incidentally, the optical scatterometry apparatus 20 may be set independent from the measuring system, in the state of being arranged side by side with the CD-SEM 1604.

The server 1606 comprises a shape feature storage unit 1607 for storing measured data of shape features of a test pattern and an actual circuit pattern, a unit 1608 for calculating the correspondence between process conditions and shape features, an actual circuit pattern calculating unit 1609, a recipe storage unit 1610, a correspondence relationship storage unit 1611 for storing the details of correlation between the actual circuit pattern shape and the test pattern shape, and a display unit 1614. Incidentally, the storage units 1607, 1610, and 1611 may be configured as a single storage unit, and the calculating units 1608 and 1609 may be configured as a single calculating unit. In addition, the ID number of a sample wafer for obtaining data for a pre-process S20, position information of a chip and that of a test pattern and a critical actual circuit pattern in the chip for measurement of the data, information on which of shape features the actual measurement is to be carried out, information on what conditions are used in manufacturing each object of measurement, and information on which of the test patterns and which of the actual patterns are associated with each other to be used for estimation of the actual pattern shape, are stored as recipes in the recipe storage unit 1610. Furthermore, the display unit 1614 may display the progress and results of a series of processing performed in the calculating units 1608 and 1609.

Next, an embodiment of the pre-process S20 for preparation and a measurement process S30 for evaluating the manufacturing process conditions at the time of manufacturing a product, according to the present invention, will be described.

First, in the pre-processing S20, a sample (semiconductor wafer) provided with patterns while varying at least one process parameter is prepared by use of the same design pattern as that for the semiconductor device intended to be measured at the mass-production stage. For example, in the photo step, patterns are baked (printed) while changing an amount of exposure and a focus value at certain intervals, to prepare a wafer called an FEM (Focus Exposure Matrix).

For the etching step, patterns are formed while varying the process parameters. It should be noted here that, unlike in the photo step, it is difficult in the etching step to form patterns while varying the process conditions on the basis of each chip formed on the wafer; in such a case, therefore, a plurality of wafers formed while varying the process conditions are used. Incidentally, in each chips on the wafer, test patterns constituted of repeated patterns which can be measured by scatterometry and actual circuit patterns are present in mixture. Here, not only the repeated patterns formed on scribe lines in the wafer but also the repeated patterns formed in each actual chip region which are measurable by scatterometry are referred to as test patterns. The test patterns have a section as shown in FIGS. 2A, 2B and 3, and are formed in areas having an appearance as shown in FIGS. 4A and 4B.

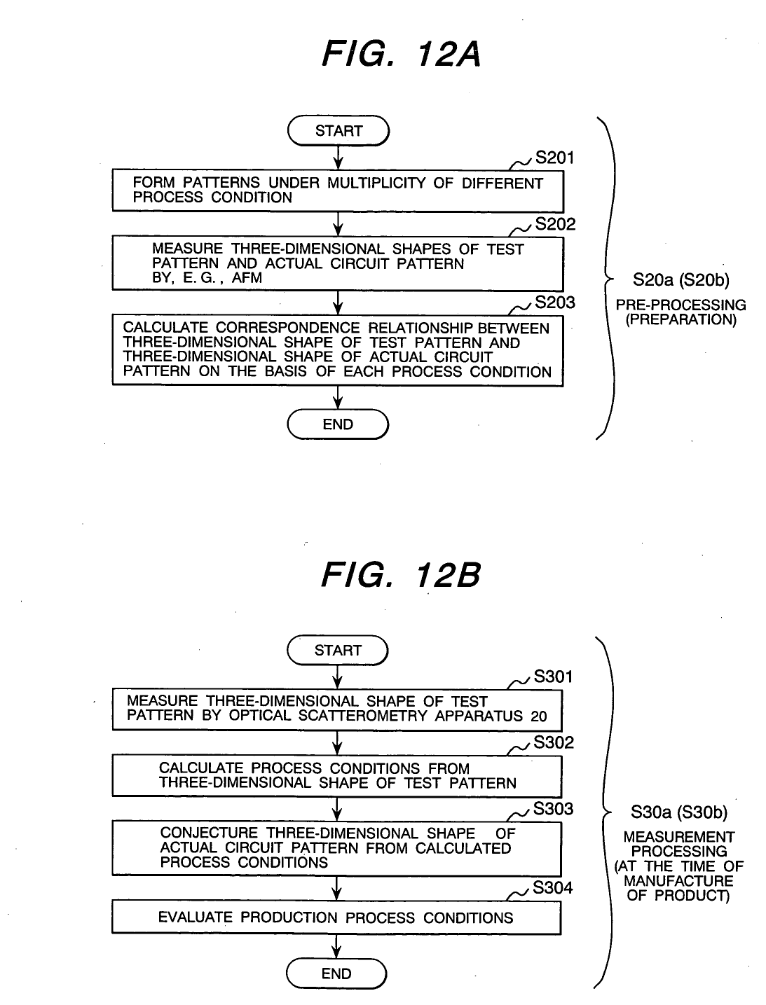

First, a first embodiment S20a of the pre-processing S20 for preparation and a first embodiment S30a of the measurement processing S30 for evaluating the manufacturing process conditions at the time of manufacturing a product, according to the present invention, will be described referring to FIGS. 12A and 12B.

The first embodiment S20a relates to the pre-processing (preparation) S20 for establishing correspondence between a test pattern and a critical portion of an actual circuit pattern according to the present invention. In addition, the first embodiment S20a is carried out by use of the first embodiment of the measuring system shown in FIG. 11, for shape model data items (the top width Wt, bottom width Wb, sidewall angle Ab, film thickness Hc, etc. noted above) in the optical scatterometry apparatus shown in FIG. 10. Specifically, as shown in FIG. 12A, a multiplicity of samples (sample wafers) provided with test patterns and actual circuit patterns under a multiplicity of different process conditions (in the case of an exposure step, an amount of exposure and focus value are varied) are prepared (S201).

Next, the sectional shape (three-dimensional shape) of the test pattern and the sectional shape (three-dimensional shape) of the circuit pattern at a plurality of critical portions are measured, for example, by use of the AFM 1604 capable of three-dimensional measurement of a pattern, and are stored in the shape feature storage unit 1607 (S202). As a result, values of the shape model data items shown in FIG. 10 (for example, a wire width and a sidewall angle, in the case of this embodiment in which process control for the exposure step is described) are obtained in the shape feature storage unit 1607. Consequently, the correspondence calculating unit 1608 can obtain pairs of the test pattern and the critical actual circuit pattern formed under the same process conditions based on the recipe information (process conditions) stored in the recipe storage unit 1610, for example, for wire width and sidewall angle of pattern. Specifically, owing to the function of the correspondence calculating unit 1608, the process conditions obtained from the recipe information and the values of, for example, wire width and sidewall angle (feature values of three-dimensional shape) of the test pattern and the critical circuit pattern are stored in the correspondence relationship storage unit 1611 in a corresponding state (S203).

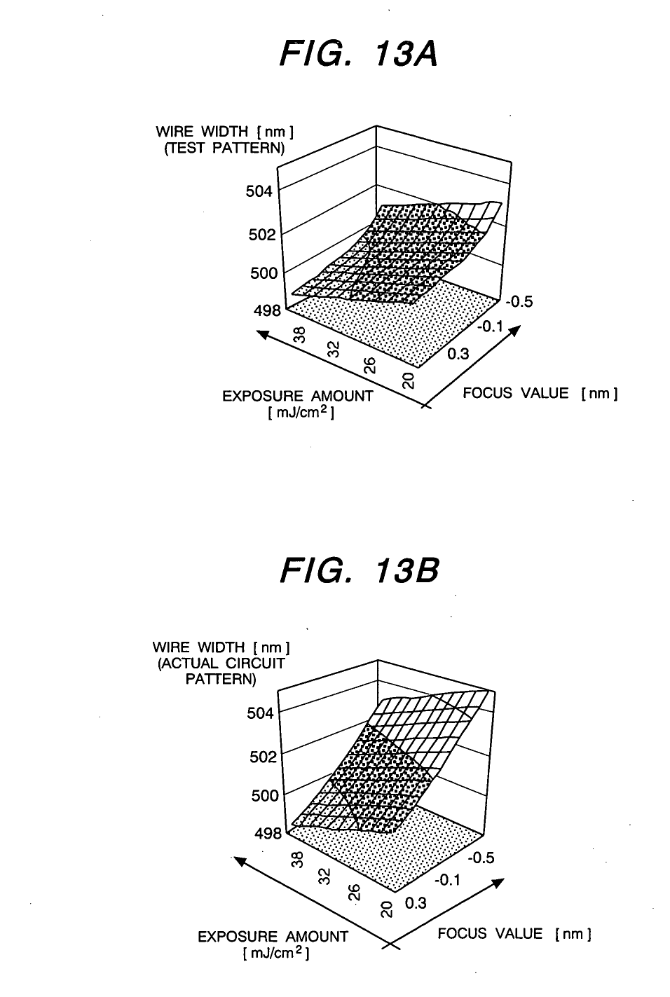

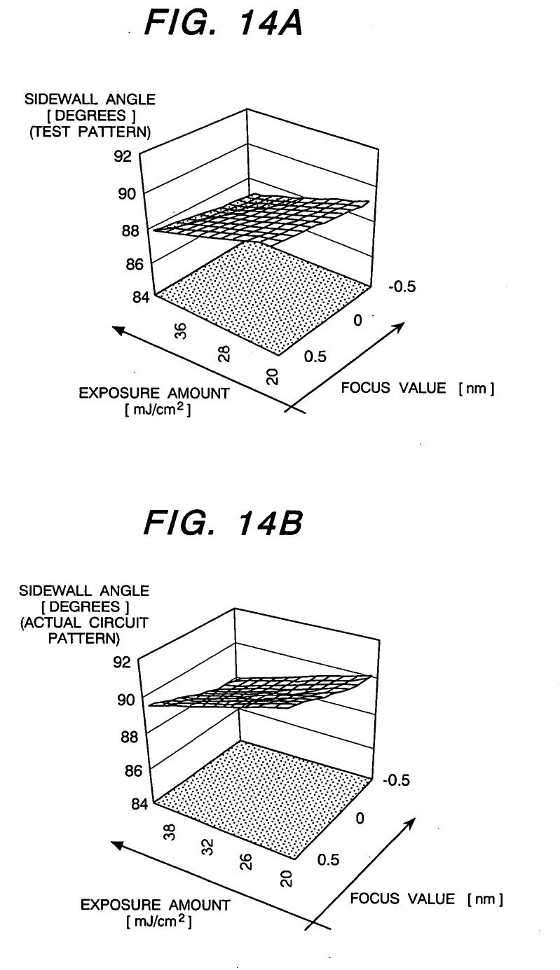

This is shown in FIGS. 13A and 13B and FIGS. 14A and 14B. In FIGS. 13A, 13B, 14A and 14B, the values of wire width and sidewall angle for the test pattern and the critical actual circuit pattern are plotted with respect to variations in an amount of exposure and a focus value and the like (values of process parameters). FIG. 13A shows variation in the wire width of the test pattern, FIG. 13B shows variation in the wire width of the actual circuit pattern, FIG. 14A shows variation in the sidewall angle of the test pattern, and FIG. 14B shows variation in the sidewall angle of the actual circuit pattern. It is seen from the figures that, for example, even in the case of patterns formed at the same values of amount of exposure and a focus value, there are differences in wire width and sidewall angle between the test pattern and the critical actual circuit pattern. This is because the actual circuit pattern is influenced by the surrounding actual circuit patterns where the patterns are super-fine. In any way, the data shown in FIGS. 13A, 13B, 14A and 14B are correspondence between the test pattern and the critical actual circuit pattern in each of the process conditions.

Next, the first embodiment S30a of the measurement processing 30 at the time of manufacturing a product will be described referring to FIG. 12B. The first embodiment S30a of evaluation of the manufacturing process conditions based on the measurement processing at the time of manufacturing a product is performed based on the first embodiment S20a of the pre-processing for setting the correspondence stored in the correspondence relationship storage unit 1611.

First, in the optical scatterometry apparatus 20, the scattered light intensity distribution for the test pattern 305 in the chip formed on the semiconductor wafer 1 produced at the time of manufacturing a product is obtained from the spectral unit (the spectrometer) 9 by use of the optical system shown in FIG. 7, and is stored in the storage unit 10.

The retrieval unit 13 obtains the sectional shape through matching to the library 12 formed preliminarily, and stores the sectional shape into the shape feature storage unit 1607 of the server 1606 through the network 1601 as shown in FIG. 11 (S301). Incidentally, the optical scatterometry apparatus 20 also can measure the feature values of the sectional shape of the test pattern, according to the recipe obtained from the server 1606.

Subsequently, since the feature values of each sectional shape are preliminarily stored in the correspondence relationship storage unit 1611 in correspondence with the process conditions for forming the test pattern in that shape, the correspondence calculating unit 1608 obtains the values of, for example, exposure amount and focus value which are the process parameters of the test pattern (i.e., calculates the process conditions) through matching to the feature values of the sectional shape of the test pattern obtained into the shape feature storage unit 1607 (S302).

Thereafter, the actual circuit pattern calculating unit 1609 uses the correspondence between the values of, for example, the amount of exposure and focus value shown in FIGS. 13A, 13B, 14A, and 14B and the differences in the feature values (wire width, sidewall angle, and the like) of three-dimensional shape between the test pattern and the critical actual circuit pattern to estimate the values of, for example, wire width and sidewall angle as the feature values of the three-dimensional shape of the critical actual circuit pattern portion in question from the values of the manufacturing process conditions (for example, exposure amount and focus value) obtained in the correspondence calculating unit 1608 (S303). The features values of the three-dimensional shape of the critical actual circuit pattern in question thus conjectured are outputted to the display unit 1614, whereby the manufacturing process conditions can be evaluated (S304).

Incidentally, the three-dimensional shape of the test pattern measured by the optical scatterometry apparatus 20, the manufacturing process conditions at the time of that three-dimensional shape, and the feature values of the three-dimensional shape of the critical actual circuit pattern estimated at the time of the manufacturing process conditions may be displayed side by side on the display unit 1614, whereby whether or not the process conditions are appropriate can be evaluated with high reliability.

Next, a second embodiment S20b of the pre-processing S20 for preparation and a second embodiment S30b of the measurement processing S30 for evaluating the manufacturing process conditions at the time of manufacturing a product, according to the present invention, will be described referring to FIGS. 12A and 12B.

In the first embodiment S20a of the pre-processing S20, the correspondence between the process conditions of the actual circuit pattern and the process conditions of the test pattern shown in FIGS. 13A, 13B, 14A and 14B are set by use of the measurement data themselves obtained, for example, by the AFM (Atomic Force Microscope). In this case, the measurement data themselves may contain errors at the time of measurement, errors at the time of formation of a pattern, etc.

In addition, in obtaining three-dimensional shape data, it is necessary to measure the patterns formed at various values of process conditions (process parameters), e.g., amounts of exposure and focus values. In order to detect the process conditions in finer units, it is necessary to make finer the variation steps of the process conditions. In this case, it is necessary to obtain much three-dimensional shape data, which is inefficient.

In view of this, the feature values of three-dimensional shape, e.g., the values of wire width and sidewall angle plotted against the process conditions, e.g., amounts of exposure and focus values are expressed by an arbitrary function approximation through fitting. For example, let the value of wire width (line width) be L, the value of amount of exposure be E, and the value of focus be F, and assuming that the wire width can be expressed by a quadratic function, then the wire width L can be expressed by the following equation (1) by use of coefficients a, b, c, d, e, f, and g:

L=aE²+bF²+cE×F+dE+eF+g (1)

Then, by using the data of the wire width L obtained by measuring patterns formed while changing the amount of exposure E and the focus value F at regular intervals and by fitting the data to the equation (1), the values of the coefficients a to g can be determined.

When this is applied to the feature values of three-dimensional shape, e.g., wire width (line width) (LR) and sidewall angle (AR) of the critical actual (real) circuit pattern, the wire width (LR) and the sidewall angle (AR) can be expressed respectively by the following equations (2) and (3):

LR=a1E²+b1F²+c1E×F+d1E+e1F+g1 (2)

AR=a2E²+b2F²+c2E×F+d2E+e2F+g2 (3)

where a{1,2}, b{1,2}, c{1,2}, d{1,2}, e{1,2}, f{1,2}, and g{1,2} are coefficients.

Therefore, for the critical actual circuit patterns present in the chips formed while varying the amount of exposure and the focus value, the wire width LR and the sidewall angle AR are measured, for example, by the AFM (Atomic Force Microscope), and are stored in the shape feature storage unit 1607. The correspondence calculating unit 1608 performs fitting of the values of the wire width LR and the sidewall angle AR thus measured to the equations (2) and (3), whereby the coefficients a{1,2} to g{1,2} can be determined. Furthermore, under the function of the correspondence calculating unit 1608, the relationships between the arbitrary amount of exposure and the arbitrary focus value and the values of wire width and sidewall angle which are the feature values of the critical actual circuit patterns can be defined by use of the coefficients a{1,2} to g{1,2} and the equations (2) and (3), and can be stored in the correspondence relationship storage unit 1611.

Next, the second embodiment S30b of the measurement processing S30 at the time of manufacturing a product will be described. The second embodiment S30b of the evaluation S30 of manufacturing process conditions based on the measurement processing at the time of manufacturing a product is performed based on the second embodiment S20b of the pre-processing for setting the correspondence preliminarily stored in the correspondence relationship storage unit 1611. That is, steps S301 to S302 are the same as those in the first embodiment. Specifically, the feature values of the three-dimensional shape of the test pattern measured by the optical scatterometry apparatus 20 are stored in the shape feature storage unit 1607 of the server 1606, and the correspondence calculating unit 1608 obtains the values of amount of exposure and focus value which are process conditions in correspondence with the feature values of the sectional shape of the test pattern measured from the correspondence relationships preliminarily stored in the correspondence relationship storage unit 1611 (S301, S302).

Thereafter, the actual circuit pattern calculating unit 1609 puts the values of amount of exposure and focus value obtained in the correspondence calculating unit 1608 into the equations (2) and (3) which are fitting functions, thereby estimating the values of, e.g., the wire width LR and sidewall angle AR of the critical actual circuit pattern under the above-mentioned process conditions (S303). In addition, the feature values of the three-dimensional shape of the critical actual circuit pattern in question thus estimated are outputted to the display unit 1614. Thus, the manufacturing process conditions can be evaluated (S304).

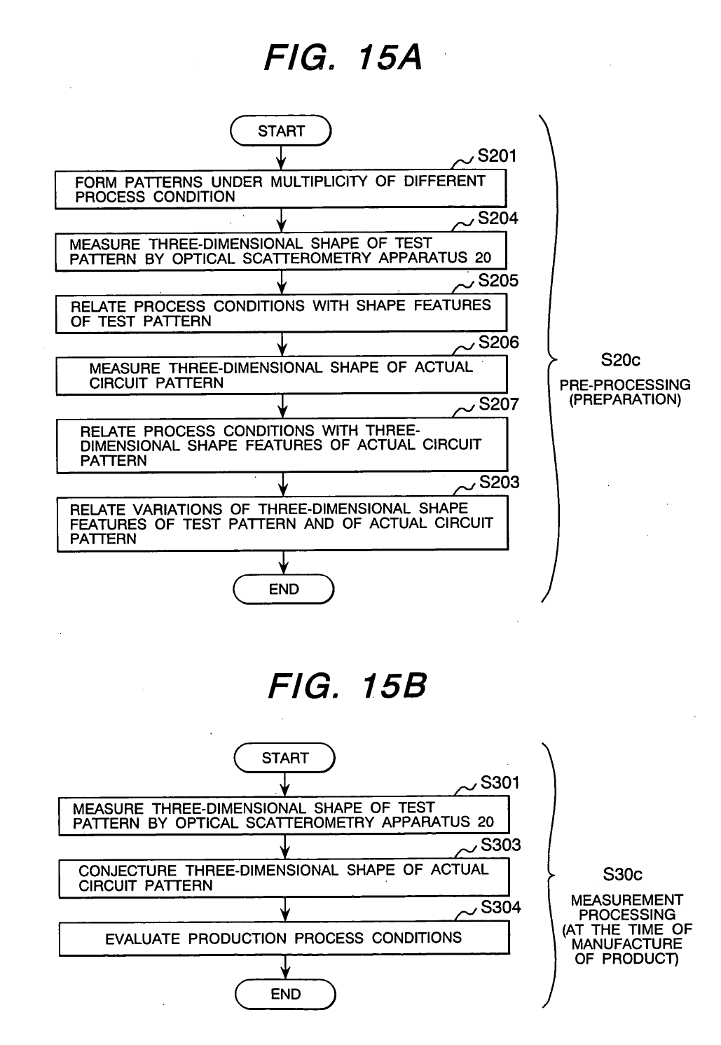

Next, a third embodiment S20c of the pre-processing for preparation and a third embodiment S30c of the measurement processing S30 for evaluating the manufacturing process conditions at the time of manufacturing a product will be described referring to FIGS. 15A and 15B.

In the third embodiment S20c of the pre-processing S20, first, in the same manner as in the first and second embodiments, semiconductor wafers provided with patterns while varying at least one process parameter are preliminarily formed by use of the same design pattern as the semiconductor device intended to be measured at the mass-production stage (S201). Next, the feature values of the three-dimensional shape of the test pattern on each semiconductor wafer are measured by use of the optical scatterometry apparatus 20.

As a result, the feature data of three-dimensional shape characterizing the sectional shape as shown in FIGS. 2A and 2B for the super-fine test patterns can be obtained from the optical scatterometry apparatus 20, and are stored in the shape feature storage unit 1607 of the server 1606 (S204). At the same time, recipe information on each semiconductor wafer is stored in the recipe storage unit 1610.

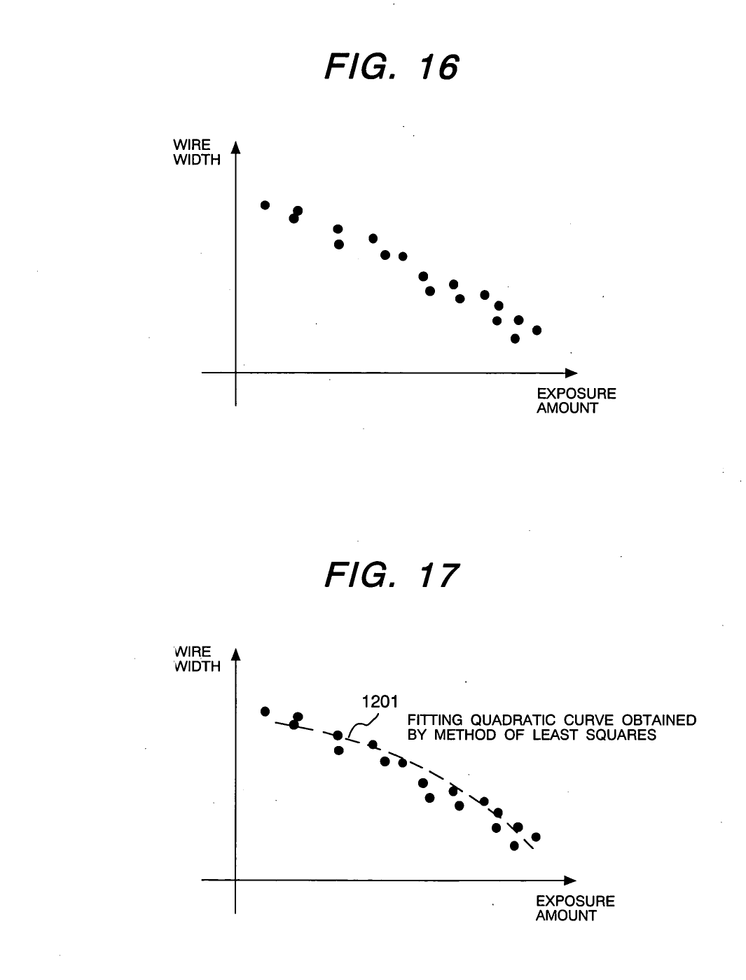

FIG. 16 shows one embodiment showing the correspondence between the values of process condition and three-dimensional shape data. In this figure, the relationship between the amount of exposure, which is one process condition in the photo step, and the wire width of a wiring pattern in the test pattern is plotted, with the amount of exposure taken on the axis of abscissas and the wire width on the axis of ordinates. From this figure, the manner of decrease of the wire width with an increase in the amount of exposure can be read. This figure shows the wire width data, which is one of the features of three-dimensional shape, on the wafers formed while fixing the other parameters than the amount of exposure. Such graphs are obtained in the number equal to the number of the features of three-dimensional shape to be defined.

In order to obtain data with high accuracy, a method may be adopted in which measurement is carried out many times for one set of process conditions instead of obtaining data once for one set of process conditions. Another method may be adopted in which data are obtained for a multiplicity of test patterns and average values for the plurality of patterns are used. Here, for ease of description, only one process parameter is varied; however, the same discussion can be applied to the cases where a plurality of process parameters are varied. In the practical photo and etching steps, generally, a plurality of process conditions are varied.

Next, the correspondence calculating unit 1608 defines correspondence relationships between the process conditions and the three-dimensional shape features based on the data stored in the shape feature storage unit 1607 and the recipe storage unit 1610, and stores the correspondence relationships into the correspondence relationship storage unit 1611 (S205). Examples of the method for this operation include a method of fitting an arbitrary function by use of the method of least squares. This method uses a function in which input values are process conditions (process parameters) and outputs are the feature values of three-dimensional shape for expressing these relationships; in practice, the process is to find a function by which the plotted data can be well expressed. Examples of the function which can be used include polynomial functions, exponential functions, and logarithmic functions. The data which can be expressed by a function differs depending on the function type and the parameters (in the case of a polynomial, the number of orders, etc.), and, therefore, optimum parameters for the function expression are preliminarily selected.

For example., the broken-line graph 1201 in FIG. 17 is a quadratic curve, which exemplifies the case of obtaining a function through fitting of the relationship between the amount of exposure and wire width shown in FIG. 16. Thus, by the function obtained from the data through fitting, the correspondence relationship between a process condition and a feature of three-dimensional shape is defined. Incidentally, this relating may be realized by other means than the function fitting process. For example, the intermediates of the process condition and the three-dimensional shape feature may be stored in the form of a table. In that case, the feature values of three-dimensional shape at intermediate values between the process conditions used for forming patterns can be obtained from the obtained data by an interpolation operation.

Next, the three-dimensional shape data on the critical actual circuit pattern in each chip are obtained by use of the AFM 1603 or the like, and are stored in the shape feature storage unit 1607 (S206). Here, since the actual circuit pattern is an arbitrary pattern other than repeated patterns measurable by the optical scatterometry apparatus, the measurement of the three-dimensional shape is conducted by use of the AFM 1607, the cross sectional SEM 1602 or the like. The infinite number of actual circuit patterns can be selected from circuit patterns, but, in general cases, an area (critical portion) with narrow margins of process conditions for normally forming the pattern is preliminarily selected. Besides, at least one actual circuit pattern may be selected from a single chip.

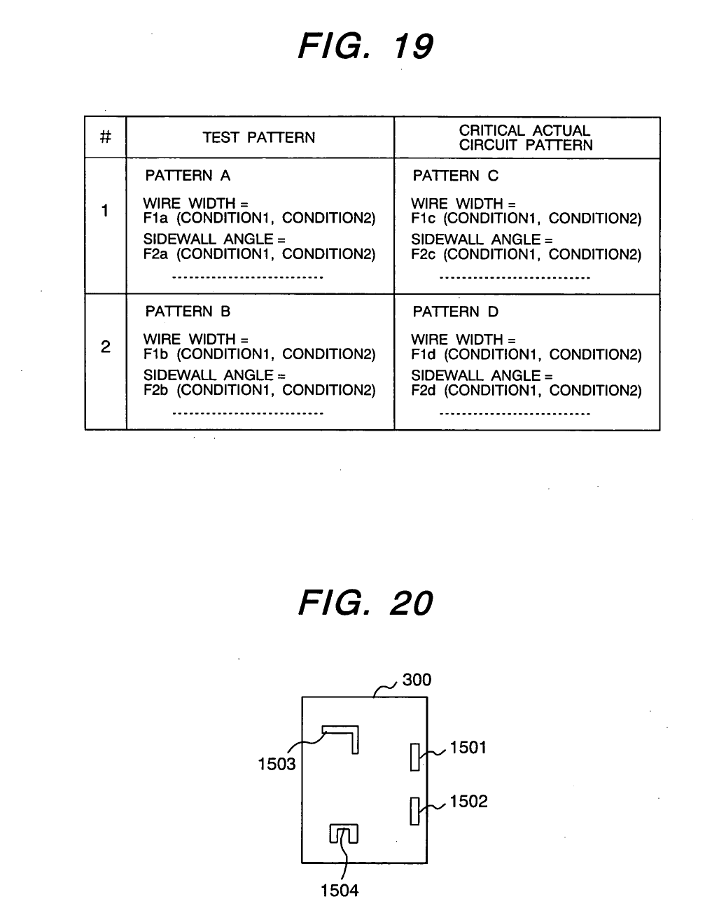

Next, the correspondence calculating unit 1608 associates the process conditions with the three-dimensional shape features, also for these pieces of data, and stores the correspondence relationships into the correspondence relationship storage unit 1611 (S207). This is performed in the same manner as the associating of process conditions with three-dimensional shape features for the test patterns through the functional fitting. Furthermore, the correspondence calculating unit 1608 relate the three-dimensional shape features of the test pattern with the three-dimensional shape features of the critical actual pattern under the same process conditions, and stores the correspondence relationships (e.g., fitting function Ft, etc.) into the correspondence relationship storage unit 1611, for example, in the format shown in FIG. 19 (S203).

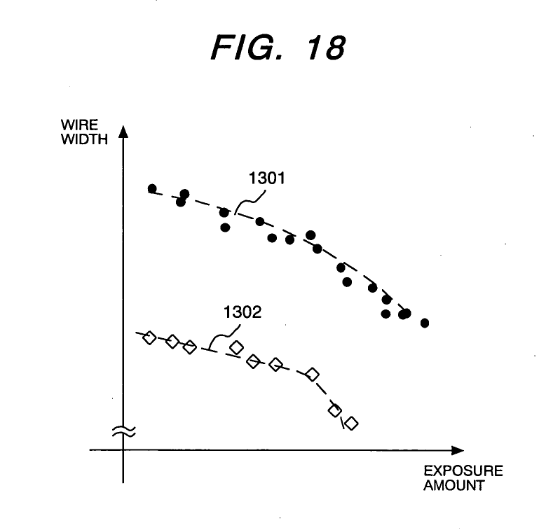

FIG. 18 is a graph showing a comparison between the three-dimensional shape feature of the test pattern and the three-dimensional shape feature of the critical actual circuit pattern under the same process conditions. The correspondence relationship between process condition and wire width value for the test pattern is indicated by solid circles, while the relationship between process condition and wire width value for the critical actual circuit pattern is indicated by void diamonds. This graph shows that the wire width decreases with an increase in the exposure amount, in both the cases of the test pattern and the critical actual circuit pattern, but there is a difference in the manner of decrease between the two cases. The difference in the influence of the process condition on the wire width arises from the difference in the influence of the process condition on the shape of the pattern depending on other patterns present in the regions surrounding each measurement region. The associating of the test pattern with the critical actual circuit pattern is realized by associating a fitting function for the data on the test pattern with a fitting function for the data on the critical actual circuit pattern.

In FIG. 18, a curve 1301 is a fitting curve for the test pattern, and a curve 1302 is a fitting curve for the critical actual circuit pattern. This can be performed, for example, by storing the data in a format as shown in FIG. 19.

FIG. 19 shows the contents stored in the condition where three-dimensional shape features and process parameters are associated with each other, for the test patterns at a plurality of locations in a chip and the critical actual circuit patterns at a plurality of locations in the chip. The individual three-dimensional shape features such as wire widths and sidewall angles are preliminarily defined in each pattern, and the correspondence relationships between the test pattern and the critical actual circuit pattern are stored in the correspondence relationship storage unit 1611.

Here, a plurality of test patterns are provided for the following reason. Generally, an actual circuit pattern comprises a multiplicity of patterns differing in wire width. Therefore, when test patterns with wire width values comparatively close to the individual wire width values of the actual circuit pattern are prepared, it is expected that the relationship between them can be held correctly. The table shown in FIG. 19 is an example of associations between two kinds of test patterns, i.e., pattern A 1501 and pattern B 1502 and the two kinds of critical actual circuit patterns, i.e., pattern C 1503 and pattern D 1504 shown in FIG. 20.

It is assumed that the test patterns A and B are line-and-space patterns, having wire widths of 50 nm and 80 nm, respectively. The actual circuit patterns intended to be measured are patterns C and D, having wire widths of 50 nm and 80 nm, respectively. In regard of the two three-dimensional shape features, i.e., wire width and sidewall angle, and for the individual patterns A, B, C, and D, the process conditions and the three-dimensional shape feature values are associated with each other by functions F1a, F2a, F1b, F2b, F1c, F2c, F1d, and F2d of which the inputs are process conditions and the output is a three-dimensional shape feature value; further, pattern A and pattern C are associated with each other, and pattern B and D are associated with each other. The process up to the step of formation of such a database is the pre-processing S20c.

Next, the third embodiment S30c of the measurement processing S30 at the time of manufacturing a product will be described referring to FIG. 15B. The third embodiment S30c for evaluating the manufacturing process conditions based on the measurement processing at the time of manufacturing a product is carried out based on the third embodiment S20c of the pre-processing for setting the correspondence stored in the correspondence relationship storage unit 1611. Specifically, in the measurement processing S30c at the time of manufacturing a product, a test pattern 305 is measured by the optical scatterometry apparatus 20, and the three-dimensional shape thereof is stored in the shape feature storage unit 1607 (S301). For the wafer 1 which is the object of measurement, the chip to be actually subjected to data measurement among the chips formed on the wafer, the coordinates of the position of the test pattern to be measured in the chip, and the kinds of the three-dimensional shape features to be measured by the optical scatterometry apparatus 20 are preliminarily set.

Next, the actual circuit pattern calculating unit 1609 estimates (guesses) the three-dimensional shape features of the critical actual circuit pattern in a chip, based on the measured values of the test pattern 305 measured by the optical scatterometry apparatus 20 stored in the shape feature storage unit 1607 and the correspondence relationships (e.g., fitting function Ft, etc.) stored in the correspondence relationship storage unit 1611 (S305). Specifically, first, based on the measured values of the test pattern 305 measured by the optical scatterometry apparatus 20, the process conditions at that time are determined. In this case, the fitting function in the pre-processing is used. For example, where an amount of exposure and a wire width are preliminarily defined as a wire width=Ft (an amount of exposure) by use of the fitting function Ft, the amount of exposure at that time can be obtained by using the inverse function of Ft and giving the wire width. Here, the manner of treating the data in the case where a plurality of process parameters are used in calculating the process parameter values will be described.

Where the process parameter is the amount of exposure alone, the amount of exposure can be obtained from the wire width by the inverse function of the fitting function of a wire width=Ft (an amount of exposure). However, where a plurality of process conditions are used, for example, where wire width=Fw (process condition 1, process condition 2), it is generally impossible to determine each of process conditions 1 and 2 from only the given wire width data. In this case, a plurality of three-dimensional shape feature values are utilized. For example, the relational equation of sidewall angle=Fs (process condition 1, process condition 2) is also preliminarily obtained in the pre-processing S20b, and process conditions 1 and 2 are calculated from the wire width data and sidewall angle data given by the two equations. In general, the process conditions can be specified by use of fitting functions the number of which is not less than the number of the process conditions to be obtained.

That is, the actual circuit pattern calculating unit 1609 calculates the three-dimensional shape feature of the critical actual circuit pattern by putting the process condition value calculated as above into the fitting function Fr for the critical actual circuit pattern, and set this value as an estimated value (S305). Here, for example, the relationship between the process condition (amount of exposure) and the three-dimensional shape feature (wire width) for the critical actual circuit pattern is defined as wire width=Fr (amount of exposure). By thus using the function obtained through fitting, the value of the three-dimensional shape feature preliminarily defined in the pre-processing S20c, for each critical actual circuit pattern in the chip, can be calculated. Once the three-dimensional shape feature of the critical actual circuit pattern is thus calculated, the user or the actual circuit pattern calculating unit 1609 can evaluate the finish of the pattern at that time point, by comparing the calculated value with a reference value (S304).

Furthermore, the measurement processing S30 at the time of manufacturing a product, which is performed in common in the first to third embodiment, will be described. When measuring a product wafer, the wafer is mounted on the optical scatterometry apparatus 20. Then, a recipe for the product wafer is transferred from the recipe storage unit 1610 of the server 1606 to the optical scatterometry apparatus 20, and measurement of the test pattern on the wafer is performed according to the contents of the recipe. The measured values thus obtained are transferred to the server 1606, and stored in the shape feature storage unit 1607. Then three-dimensional shape feature values of the critical actual circuit pattern in the chip set in the recipe are calculated in the actual circuit pattern calculating unit 1609. The calculated results are displayed on the display unit 1614, whereby the manufacturing process conditions can be evaluated. Furthermore, the calculated values are sent to the manufacturing apparatuses such as the exposure apparatus 1612 and the etcher 1613, where the manufacturing process is controlled based on the data thus obtained.

While the various measuring instruments and the server 1606 are connected to each other through the network 1601 in the above embodiments, the present invention is not limited to such a configuration. For example, the functions of the server 1606 may be incorporated in the measuring instruments or the manufacturing apparatuses.

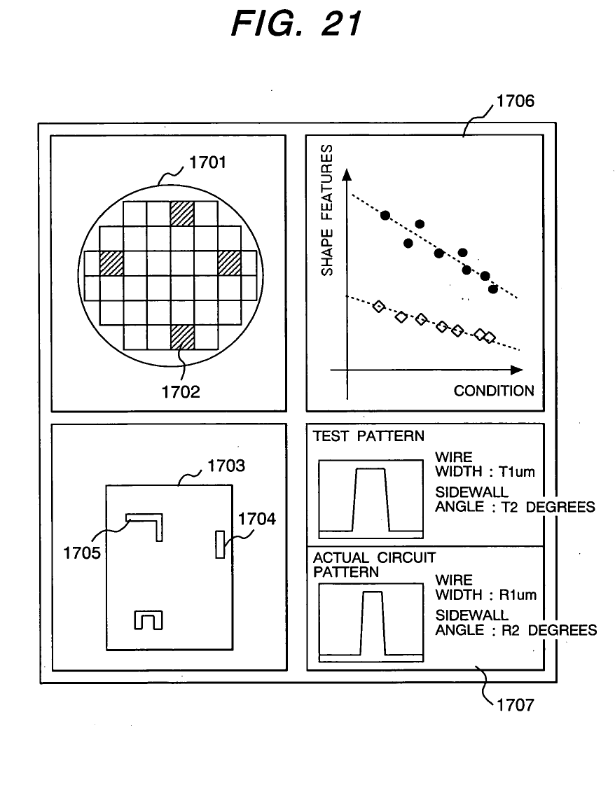

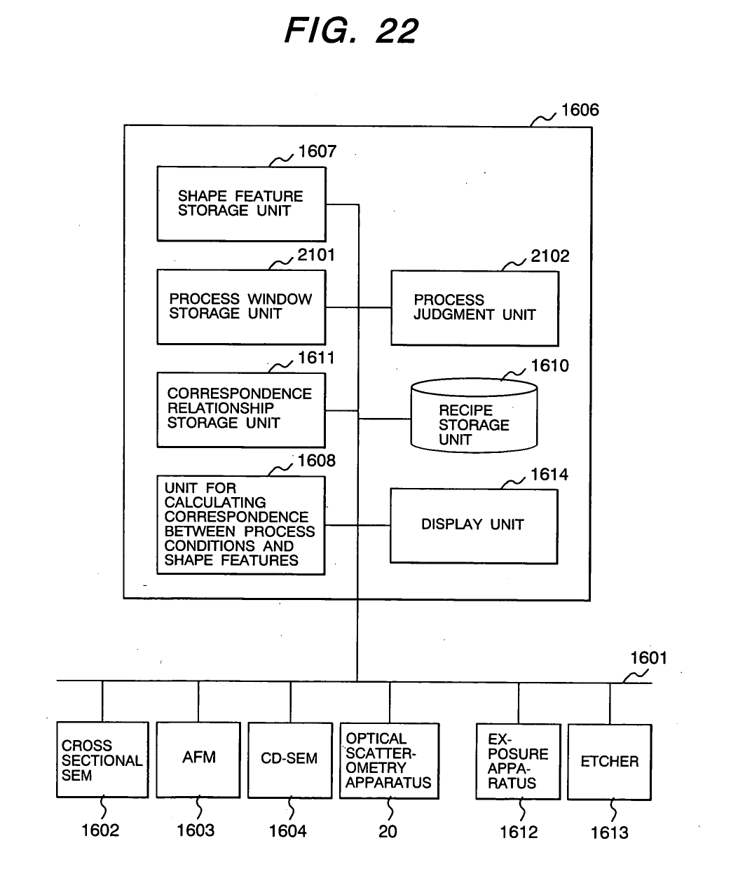

In such a system, the information as shown in FIG. 21, for example, is displayed on the display unit 1614 in the server 1606 and in each measuring instrument or on a display unit (not shown) in the manufacturing apparatus. Specifically, the layout 1701 in the wafer under measurement is displayed, and the chips 1702 measured are highlighted. Furthermore, the layout 1703 of the chip to be measured is displayed, and a graph representing the relationships of the three-dimensional shape feature of a test pattern 1704 obtained in the pre-processing S20 and the three-dimensional shape feature of a critical actual circuit pattern 1705 with the process conditions are displayed in a graph display area 1706. In addition, the measured values of the test pattern and the feature values of the critical actual circuit pattern calculated therefrom are displayed in a shape display area 1707 together with the shape models. Furthermore, when a chip is designated in the wafer layout 1701 or when a critical actual circuit pattern is designated in the chip layout 1703, data corresponding to the designated portion are displayed in the shape display area 1707.

With such a display unit provided, the user can grasp the three-dimensional shapes of the test pattern measured and the actual circuit pattern in question. Then, by checking whether or not the three-dimensional shape of the actual circuit pattern is within the criteria, it is possible to check whether a problem exists in the process, whether the process is not varied, and so on.

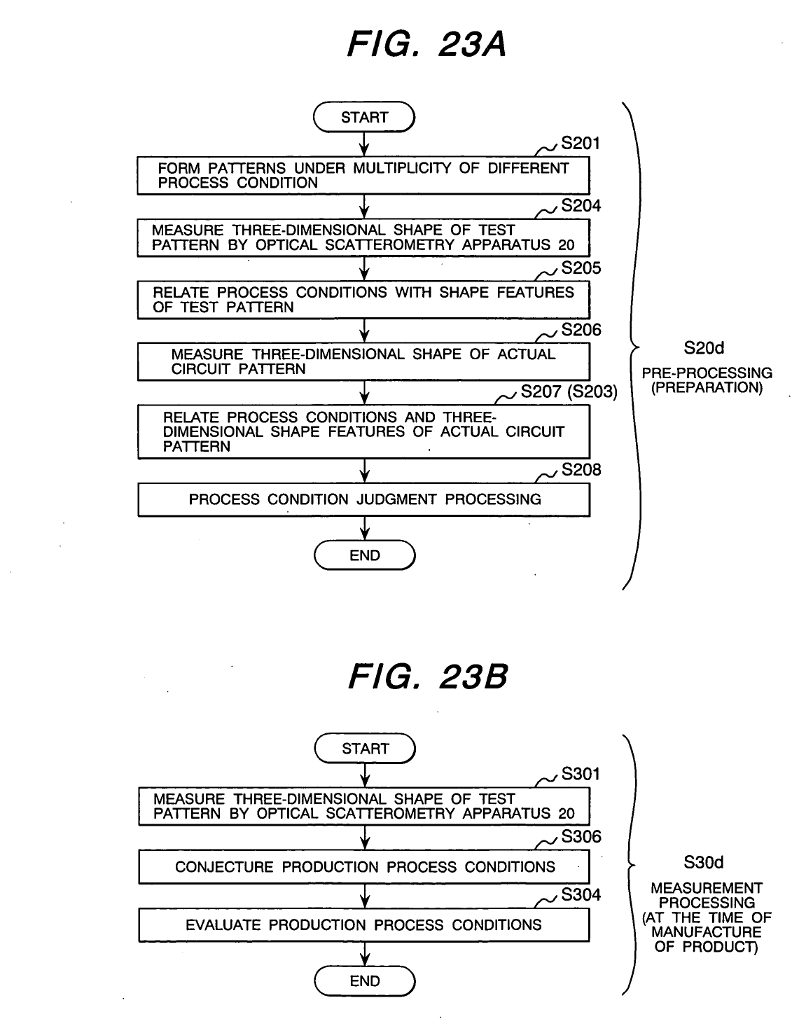

Next, a fourth embodiment S20d of the pre-processing S20 for preparation and a fourth embodiment S30d of the measurement processing S30 for evaluating the manufacturing process conditions at the time of manufacturing a product, according to the present invention, will be described referring to FIGS. 22, 23A and 23B.

FIG. 22 illustrates a second embodiment of the measuring system, which is a system for manufacturing a semiconductor device, for carrying out the fourth embodiments. The second embodiment of the measuring system differs from that in the first embodiment shown in FIG. 11 in that a process judging unit 2102 is provided in place of the actual circuit pattern calculating unit 1609 in the server 1606, and, further, a process window storage unit 2101 is provided in the server 1606. With this modification, information on which test pattern and which actual circuit pattern are to be put into a corresponding relationship to define a process window is stored as a recipe in the recipe storage unit 1610.

FIGS. 23A and 23B show flow charts for illustrating a process monitoring method according to the present invention. The present flow is constituted of a pre-processing S20d for preparation and a post-processing S30d for evaluating the manufacturing process conditions at the time of manufacturing a product. Of the pre-processing S20d, the other portions than a process condition judging processing S208 are the same as those in the pre-processing S20a to S20c for the measurement processing in the first to third embodiments shown in FIGS. 12A and 15A, and description thereof is therefore omitted.

In the process condition judging processing S208, a correspondence calculating unit 1608 sets process conditions for manufacturing actual circuit pattern areas (particularly, a critical portion) in conformity with the criteria for the three-dimensional shape of the circuit pattern. Specifically, the correspondence calculating unit 1608 determines the manufacturing process conditions suitable for forming each actual circuit pattern in conformity with the criteria, based on the three-dimensional shape of each of actual circuit patterns formed while varying the manufacturing process conditions (process parameters) in various ways stored in a shape feature storage unit 1607.

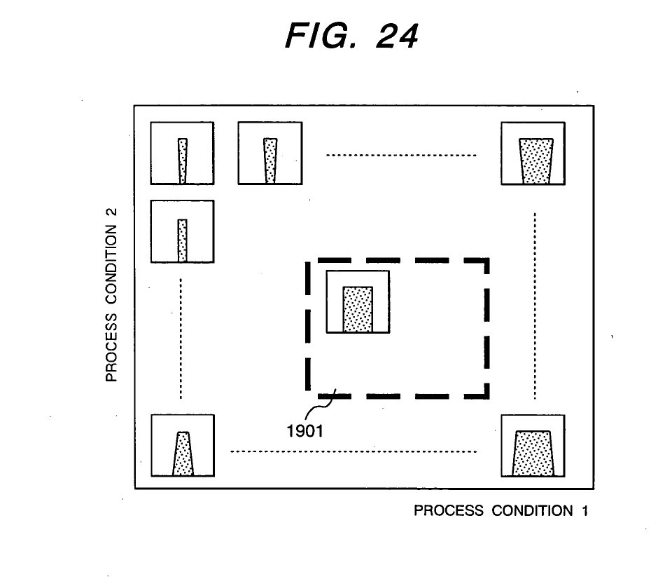

The correspondence calculating unit 1608 displays on a display unit 1614 sectional changes (gray areas are pattern areas) of actual circuit patterns formed while varying, for example, two manufacturing process conditions as shown in FIG. 24, and designates and inputs such process conditions that the pattern shape is within the criteria, whereby it is possible to determine the manufacturing process conditions under which the actual circuit pattern can be formed in conformity with the criteria. In the figure, the area surrounded by the thick broken line is generally called a process window 1901, and means the ranges of the process conditions within which the pattern satisfies the criteria. In this pre-processing S20d, when the three-dimensional shapes of a plurality of critical actual circuit patterns and test patterns are measured, such process windows are defined on the basis of each measurement region, namely, in the number equal to the number of the individual critical circuit patterns and test patterns.

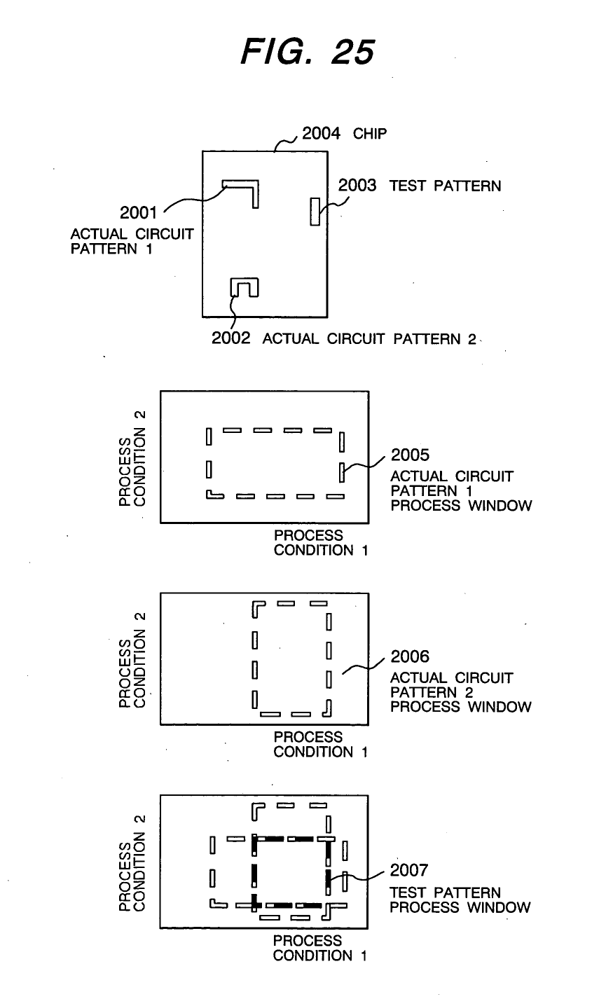

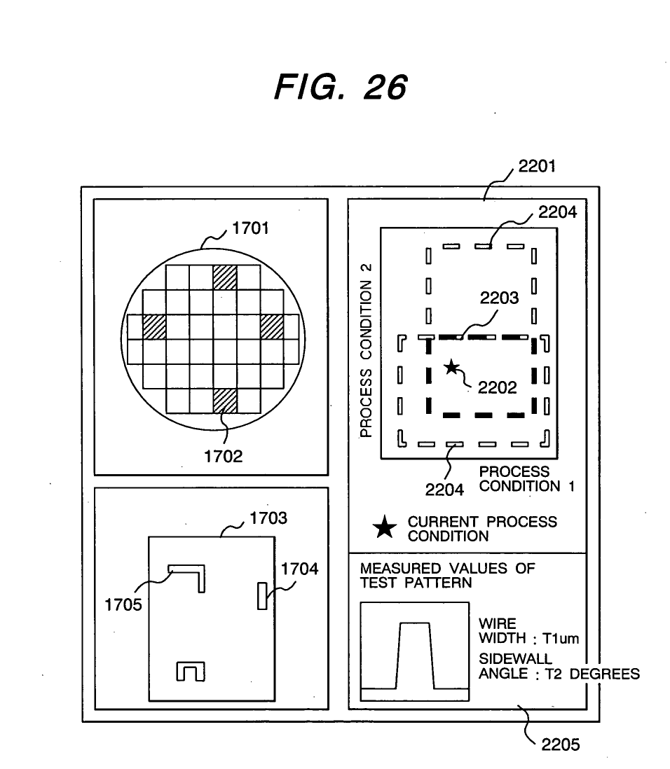

FIG. 25 illustrates the manner of definition of the process windows, in which the relationships between the process windows for a critical actual circuit pattern 1 (2001), a critical actual circuit pattern 2 (2002), and a test pattern 2003 are shown. First, the correspondence calculating unit 1608 determines the respective process windows for the critical actual circuit patterns stored in the shape feature storage unit 1607. Here, the actual circuit patterns in conformity with the criteria (acceptable products), i.e., the criteria for the normally formed actual circuit patterns may be the same or different. Where the patterns in the actual circuit have different roles, the criteria for the patterns may be different. In the figure, the thick broken lines 2005 and 2006 indicate the process windows for the actual circuit patterns 1 and 2, and, here, the ranges of the process conditions are different between the two process windows.

Then, an overlapping portion 2007 of the process windows 2005 and 2006 meaning the process conditions under which the plurality of critical actual circuit patterns can be formed normally is obtained, and is stored in the process window storage unit 2101 as a process window for a test pattern. That is, the process window 2007 determined for the test pattern means the process conditions under which the plurality of critical actual circuit patterns can be formed normally.

In this manner, in the pre-processing S20d, the three-dimensional shape feature data on the test patterns formed while varying the process conditions are stored in the shape feature storage unit 1607. The process condition values at those times are stored in the recipe storage unit 1610. In addition, data on the process window 2007 corresponding to the test patterns are stored in the process window storage unit 2101. This ensures that the correspondence calculating unit 1608 can take the correspondence between the three-dimensional shape of the test pattern and the process conditions suitable for normally manufacturing the critical actual circuit patterns, based on the data on the process window 2007 for the test patterns stored in the process window storage unit 2101, and the correspondence relationship can be stored in a correspondence relationship storage unit 1611.

Next, the fourth embodiment S30d of the measurement processing S30 for evaluating the manufacturing process conditions at the time of manufacturing a product will be described. In the fourth embodiment S30d, first, a test pattern on a product wafer is measured by the optical scatterometry apparatus 20, and the three-dimensional shape features of the test pattern are obtained, and are stored in the shape feature storage unit 1607. Then, the process judging unit 2102 specifies, by use of the three-dimensional shape features of the test pattern stored in the shape feature storage unit 1607, the process conditions based on, and at the time of, the correspondence relationship between the three-dimensional shape features and the process conditions stored in the correspondence relationship storage unit 1611.

Furthermore, the process judging unit 2102 compares the correspondence relationship between the manufacturing process conditions (e.g., process condition 1 and process condition 2) and the process window (e.g., the overlapping area 2007) for the critical actual circuit patterns preliminarily obtained in the pre-processing S20d with the manufacturing process conditions at that time, to judge whether or not the manufacturing process conditions at that time are appropriate, whereby the results of the judgment can be outputted to a display unit 1614 provided as an output unit. In this case, it is possible to output an alternative judgment of whether or not the current manufacturing process conditions are within the process window, i.e., whether or not the current process is acceptable, and also to perform a finer process control.

For example, when the center, for example, of the process window 2007 for the test pattern, which is the overlapping area of the process windows 2005 and 2006 for a plurality of critical actual circuit patterns in FIG. 25 is defined as optimum values of the manufacturing process, the process judging unit 2102 can calculate the deviations of the current manufacturing process conditions from the optimum values, and can feed back the amounts of deviation to the manufacturing apparatuses such as an exposure apparatus 1612 and an etcher 1613 through a network 1601, whereby the manufacturing process can be controlled (corrected).

Incidentally, in the second embodiment of the measuring system, information as shown in FIG. 26, for example, can be displayed on the display unit 1614 in the server 1606 and/or on a display unit (not shown) in each measuring instrument or manufacturing apparatus. Specifically, the layout 1701 in the wafer under measurement is displayed, and the chips 1702 measured are highlighted. The layout 1703 in the chip which is the object of measurement is displayed, and a process window 2204 for the critical actual circuit pattern and a process window 2203 for the test pattern which are obtained from the pre-processing S20d are displayed in a process window display area 2201.

In addition, the measured values of the test pattern are displayed in a display area 2205 for measured values of test pattern, and the process conditions 2002 calculated from the measured values are displayed in the process window display area 2201. With such a display unit provided, it is possible to confirm whether a problem exists in the process, whether the process is not varied, and so on.

While various measuring instruments and the server 1606 are connected to each other through the network 1601 in the above embodiment, the present invention is not limited to such a configuration. For example, the functions of the server 1606 may be incorporated in the measuring instruments and/or manufacturing apparatuses.

As has been described above, according to the present invention, it is possible to manufacture a semiconductor device while enabling evaluation of the manufacturing process for a super-miniaturized actual circuit pattern at a high speed by utilizing a three-dimensional measuring technique based on the use of an optical scatterometry apparatus.

In addition, according to the present invention, such a control of the manufacturing process as to make appropriate the finish of the super-miniaturized actual circuit pattern can be controlled, based on the three-dimensional measurements of the test pattern by the optical scatterometry apparatus.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

1. A method of manufacturing a semiconductor device, comprising the steps of:
forming a test pattern and an actual circuit pattern on a semiconductor substrate by a predetermined semiconductor manufacturing process;
measuring a feature of the three-dimensional shape of said test pattern formed on said semiconductor substrate by use of an optical scatterometry apparatus; and
evaluating said semiconductor manufacturing process for said actual circuit pattern on said semiconductor substrate based on a result of said measurement.

2. A method of manufacturing a semiconductor device as set forth in claim 1, wherein said predetermined semiconductor manufacturing process is an exposure and development process.

3. A method of manufacturing a semiconductor device as set forth in claim 1, wherein said predetermined semiconductor manufacturing process is an etching process.

4. A method of manufacturing a semiconductor device, comprising:
a preparation step comprising the steps of:
preliminarily forming a sample wafer provided with a test pattern and an actual circuit pattern while varying a process parameter in a semiconductor manufacturing process;
measuring a feature of the three-dimensional shape of said test pattern formed as said sample wafer and a feature of the three-dimensional shape of a predetermined portion of an actual circuit pattern formed as said sample wafer; and
calculating and preparing a correspondence relationship between said three-dimensional shape feature of said test pattern and said three-dimensional shape feature of said predetermined portion of said actual circuit pattern measured while varying said process parameter; and
an evaluation step comprising the steps of:
measuring a feature of the three-dimensional shape of a test pattern formed in a product semiconductor device by use of an optical scatterometry apparatus, at the time of manufacturing said product semiconductor device by forming said test pattern and an actual circuit pattern by a predetermined product semiconductor manufacturing process; and
evaluating said semiconductor manufacturing process for said actual circuit pattern of said product semiconductor device from said correspondence relationship at the time of varying said process parameter prepared in said preparation step, based on said measured feature of said three-dimensional shape of said test pattern.

5. A method of manufacturing a semiconductor device as set forth in claim 4, wherein in said preparation step, said measurement of said feature of said three-dimensional shape of said test pattern and said feature of said three-dimensional shape of said predetermined portion of said actual circuit pattern is carried out by an AFM observation.

6. A method of manufacturing a semiconductor device as set forth in claim 4, wherein in said preparation step, said measurement of said feature of said three-dimensional shape of said test pattern is carried out by use of an optical scatterometry apparatus, and said measurement of said feature of said three-dimensional shape of said predetermined portion of said actual circuit pattern is carried out by an AFM observation or a cross sectional SEM observation.

7. A method of manufacturing a semiconductor device as set forth in claim 4, wherein in said preparation step and said evaluation step, said semiconductor manufacturing process is a semiconductor exposure and development step, and said process parameter in said semiconductor manufacturing process is at least one selected from the group consisting of an amount of exposure and a focus value.

8. A method of manufacturing a semiconductor device as set forth in claim 4, wherein in said preparation step and said evaluation step, said semiconductor manufacturing process is a semiconductor etching process, and said process parameter in said semiconductor manufacturing process is at least one selected from the group consisting of a gas flow rate, pressure variation, and etching time.

9. A method of manufacturing a semiconductor device as set forth in claim 4, wherein a fitting function is used for each said process parameter, in calculating said correspondence relationship between said feature of said three-dimensional shape of said test pattern and said feature of said three-dimensional shape of said predetermined portion of said actual circuit pattern at the time of varying said process parameter, in said preparation step.

10. A method of manufacturing a semiconductor device as set forth in claim 4, wherein a process window set for each said process parameter is used, in calculating said correspondence relationship between said feature of said three-dimensional shape of said test pattern and said feature of said three-dimensional shape of said predetermined portion of said actual circuit pattern at the time of varying said process parameter, in said preparation step.

11. A method of manufacturing a semiconductor device, comprising:
a preparation step which comprises the steps of preliminarily forming a sample wafer provided with a test pattern and an actual circuit pattern while varying a process parameter in a semiconductor manufacturing process, measuring a feature of a three-dimensional shape of said test pattern formed as said sample wafer and a feature of a three-dimensional shape of a predetermined portion of said actual circuit pattern formed as said sample wafer, and calculating and preparing a correspondence relationship between said feature of said three-dimensional shape of said test pattern and said feature of said three-dimensional shape of said predetermined portion of said actual circuit pattern measured while varying said process parameter; and
an evaluation step which comprises, in manufacturing a product semiconductor device by forming a test pattern and an actual circuit pattern by a predetermined product semiconductor manufacturing process, the steps of measuring a feature of the three-dimensional shape of said test pattern formed in said product semiconductor device by use of an optical scatterometry apparatus, estimating a feature of the three-dimensional shape of a predetermined portion of said actual circuit pattern based on said correspondence relationship at the time of varying said process parameter prepared in said preparation step, and evaluating said semiconductor manufacturing process for said actual circuit pattern of said product semiconductor device based on said estimated three-dimensional shape feature.

12. A method of manufacturing a semiconductor device, comprising:
a preparation step which comprises the steps of preliminarily forming a sample wafer provided with a test pattern and an actual circuit pattern while varying a process parameter in a semiconductor manufacturing process, measuring a feature of the three-dimensional shape of said test pattern formed as said sample wafer and a feature of the three-dimensional shape of a predetermined portion of said actual circuit pattern formed as said sample pattern, setting a range of said process parameter necessary for said three-dimensional shape feature of said predetermined portion of said actual circuit pattern measured while varying said parameter to satisfy a reference three-dimensional shape feature, and calculating and preparing said measured three-dimensional shape feature of said test pattern in said set range of said process parameter; and
an evaluation step which comprises, in manufacturing a product semiconductor device by forming a test pattern and an actual circuit pattern by a predetermined product semiconductor manufacturing process, the steps of measuring a feature of the three-dimensional shape of said test pattern formed in said product semiconductor device by use of an optical scatterometry apparatus, judging whether or not said measured three-dimensional shape feature of said test pattern is within said range of said process parameter prepared in said preparation step, based on said calculated three-dimensional shape feature of said test pattern within said range of said process parameter, and thereby evaluating said semiconductor manufacturing process for said actual circuit pattern of said product semiconductor device.

13. A method of manufacturing a semiconductor device as set forth in claim 10, wherein in said preparation step and said evaluation step, a range of said process parameter is said process window.

14. A system for manufacturing a semiconductor device, comprising:
a preparation unit for preliminarily measuring, for a plurality of sample wafers provided with a test pattern and an actual circuit pattern while varying a process parameter in a semiconductor manufacturing process, a feature of the three-dimensional shape of said test pattern and a feature of the three-dimensional shape of a predetermined portion of said actual circuit pattern, and calculating and preparing a correspondence relationship between said three-dimensional shape feature of said test pattern and said three-dimensional shape feature of said predetermined portion of said actual circuit pattern measured while varying said process parameter; and
an evaluation unit, in manufacturing a product semiconductor device by forming a test pattern and an actual circuit pattern by a predetermined product semiconductor manufacturing process, for measuring a feature of the three-dimensional shape of said test pattern formed in said product semiconductor device by use of an optical scatterometry apparatus, and evaluating said semiconductor manufacturing process for said actual circuit pattern of said product semiconductor device from said correspondence relationship at the time of varying said process parameter prepared by said preparation unit, based on said measured three-dimensional shape feature of said test pattern.

15. A system for manufacturing a semiconductor device as set forth in claim 14, further comprising an unit for feeding back the information on said semiconductor manufacturing process evaluated by said evaluation unit to a manufacturing apparatus.
